(19) United States
(12) Patent Application Publication
(10) Pub. No.: US 2011/0254062 A1
(43) Pub. Date: Oct. 20, 2011

(54) FIELD EFFECT TRANSISTOR AND METHOD OF MANUFACTURING THE SAME

(75) Inventors: Tatsuo Shimizu, Tokyo (JP); Atsuhiro Kinoshita, Kanagawa-Ken (JP); Hirotaka Nishino, Kanagawa-Ken (JP)

(73) Assignee: KABUSHIKI KAISHA TOSHIBA, Tokyo (JP)

(21) Appl. No.: 13/042,590

(22) Filed: Mar. 8, 2011

(30) Foreign Application Priority Data
Apr. 19, 2010 (JP) 2010-095992

(51) Int. Cl. H01L 29/772; H01L 21/8238; H01L 21/336

(52) U.S. Cl. 257/288; 438/299; 438/218; 257/E29.242; 257/E21.409; 257/E21.632

(57) ABSTRACT

A field effect transistor which can operate at a low threshold value includes: an n-type semiconductor region; a source region and a drain region separately formed in the n-type semiconductor region; a first insulating film formed in the semiconductor region between the source region and the drain region and containing silicon and oxygen; a second insulating film formed on the first insulating film and containing at least one material selected from Hf, Zr, and Ti and oxygen; and a gate electrode formed on the second insulating film. Ge is doped in an interface region including an interface between the first insulating film and the second insulating film, and an area density of the Ge has a peak on a first insulating film side in the interface region.

### CROSS REFERENCE TO RELATED APPLICATION

This application is based upon and claims the benefit of priority from the prior Japanese Patent Application No. 2010-095992 filed in Japan on Apr. 19, 2010; the entire contents of which are incorporated herein by reference.

### FIELD

The present invention relates a field effect transistor and a method of manufacturing the same.

### BACKGROUND

Conventionally, in order to secure an amount of charge excited in a channel of a MISFET (metal insulator semiconductor field effect transistor), a method of thinning a gate insulating film to increase a capacity has been employed. As a result, thinning of a SiO₂ film serving as a gate insulating film is advanced. At the present, the film thickness of the SiO₂ film reaches a thickness which is considerably smaller than 1 mm.

At this moment, a gate leakage current increases in the SiO₂ film, a power consumption cannot be suppressed because a standby power is scattered and lost. For example, a SiO₂ film having a film thickness of 0.8 nm has a gate leakage current which reaches 1 kA/cm² to pose a very serious problem in terms of power consumption.

In order to reduce a power consumption, increasing in film thickness is effective. For this reason, a material (high-k dielectric) having a dielectric constant larger than that of the SiO₂ film, an insulating film can secure an amount of charge even though the insulating film is thicker than the SiO₂ film. Many metal oxides are known as stable materials having high dielectric constants.

As an insulating film having the characteristics, at the present, regard as a promising insulating film, include a film consisting of HfO₂, ZrO₂, and a silicate thereof, a film (HfON, HfSiON) consisting of a nitride thereof, and the like.

However, when these insulating films are used as gate insulating films, another problem arises that a small threshold value cannot be obtained. When a SiO₂ film and a high-dielectric-constant film are used, an effective work function tends to be large in an nMISFET, and an effective work function tends to be small in a pMISFET. This is known as a phenomenon called a Fermi-level pinning between an insulating film having a high dielectric constant and an electrode.

In order to solve this problem, a method of diffusing Al in a gate insulating film in a pMIS transistor to change a pinning position of a Fermi level is proposed in M. Kadoshima et. al. 2007 VLSI Technology Digest P66, wherein Al is diffused in a gate insulating film in a pMIS transistor to change a pinning position. However, in the pMIS transistor in which Al is diffused, the following problems are given.

(1) A voltage shift which is enough to realize a sufficiently low threshold value cannot be obtained, and

(2) Mobility is deteriorated.

More specifically, in order to satisfy performances required in a next-generation or later CMIS

(Complementary-Metal-Insulator-Semiconductor) transistor, for example, a low-threshold operation, another technique which optimizes an effective work function is necessary.

### BRIEF DESCRIPTION OF THE DRAWINGS

FIGS. 1A, 1B, and 1C are diagrams for explaining a mechanism which can make interface dipole by doping Ge in a pMISFET according to the embodiment.

FIG. 2A is a diagram showing an example of structure of an interface between a SiO₂ film and a high-dielectric-constant film (HfO₂ film), and FIG. 2B is a diagram for explaining an electronic state in the interface between the SiO₂ film and the high-dielectric-constant film.

FIG. 3A shows an example of structure in which F is doped in an interface between the SiO₂ film and a high-dielectric-constant film, and FIG. 3B shows an example of structure in which N is doped.

FIGS. 4A, 4B, and 4C are diagrams for explaining states in which a system is stabilized by doping fluorine in an interface.

FIG. 5 is a diagram showing a distribution of fluorine in a film thickness direction when fluorine is doped in an interface.

FIGS. 6A, 6B, 6C, and 6D are diagrams showing states in which a system is stabilized by doping nitrogen in an interface.

FIG. 7 is a diagram showing a distribution of nitrogen in a film thickness direction when nitrogen is doped in an interface.

FIG. 8 is a diagram showing a distribution of Ta in a film thickness direction when Ta is doped in an interface.

FIG. 9 is a diagram showing a distribution of Ge in a film thickness direction when Ge is doped in an interface.

FIGS. 10A, 10B, and 10C are diagrams showing polarization forming patterns by a fixed charge in a pMISFET.

FIGS. 11A, 11B, and 11C are schematic diagrams for explaining a schematic method of manufacturing of a pMISFET according to a first embodiment.

FIGS. 12A, 12B, 12C, 12D, and 12E are schematic diagrams for explaining a method of manufacturing the pMISFET according to the first embodiment.

FIG. 13 is a sectional view showing the pMISFET according to the first embodiment.

FIGS. 14A and 14B are diagrams showing a CV curve the threshold value of which moves by doping Ge in a pMISFET according to Variation 2 of the first embodiment.

FIGS. 15A, 15B, and 15C are schematic diagrams for explaining a method of manufacturing a CMISFET according to a second embodiment.

FIGS. 16A, 16B, and 16C are diagrams for explaining an additive to design a low-threshold structure of the pMISFET according to the embodiment.

### DETAILED DESCRIPTION

A field effect transistor according to one aspect of the present invention includes: an n-type semiconductor region; a source region and a drain region separately formed in the n-type semiconductor region; a first insulating film formed in the n-type semiconductor region between the source region and the drain region and containing silicon and oxygen; a second insulating film formed on the first insulating film and containing at least one element selected from Hf, Zr, and Ti and oxygen; and a gate electrode formed on the second insulating film, wherein Ge is doped in an interface region including an interface between the first insulating film and the second insulating film, and an area density of the Ge has a peak on a first insulating film side in the interface region.

A method of manufacturing a field effect transistor according to one aspect of the present invention includes: the step of forming a first insulating film on an n-type semiconductor region; the step of depositing a material containing Ge on the first insulating film; the step of forming a second insulating film to cover the material containing the Ge; the heat treatment step of diffusing the material containing the Ge in an interface region including an interface between the first insulating film and the second insulating film; the step of forming a gate electrode on the second insulating film; and the step of forming a source region and a drain region which are separated from each other in the n-type semiconductor region by using the gate electrode as a mask.

Embodiments will be described below in detail with reference to the accompanying drawings.

The principle of a field effect transistor according to the embodiment will be described.

First, control of an effective work function in the embodiment will be described.

(Relationship Between Valence of Element Constituting Insulating Film and Valence of Additive Element)

A case in which an insulating film consists of an element M and oxygen and the element M is substituted by an additive element A will be considered. When the additive element A has a valence smaller than that of the element M, a substantially negative charge seems to be present in an insulating film. In contrast, when the additive element A has a valence larger than that of the element M, a substantially positive charge seems to be present in an insulating film. Here, it should be noticed to refer that the electric charge (excessive charge) substantially seems to be present. That is, an electric charge which effectively seems to be present is not generated, when the additive element A and oxygen make an insulating material to directly diffuse the insulating material in an insulating film.

For example, in a state in which Al₂O₃ (or La₂O₃) is diffused in an HfO₂ film, an excessive charge is not generated. In this case, the insulating film can be described as nHfO₂+mAl₂O₃ (n and m are appropriate positive integers). In contrast, when a metal Hf of HfO₂ is substituted by a metal Al (or metal La), a negative 1 valence (−1) substantially exists in a site in which Hf is substituted by Al, since +3 Al has entered a site in which +4 valences of Hf originally existed. Which state is generated, i.e., which state is more stable considerably depends on an ion radius. Details of this problem will be described later. When a metal of HfO₂ is substituted by a metal Ta, a positive 1 valence (+1) effectively exists in the site in which Hf is substituted by Ta, since +5 Ta has entered a site in which +4 valences of Hf originally existed in a site.

Similarly, a state in which La₂O₃ is diffused in an SiO₂ film can be described by nSiO₂+mLa₂O₃ (n and m are appropriate positive integers), and an excessive charge is not generated in the SiO₂ film. In particular, a material is called silicate when the material constituting an insulating film is silicon. For example, La₂SiO₅ (=SiO₂+La₂O₃) is one type of La silicate. In contrast, when Si in SiO₂ is substituted by a metal Al, a negative 1 valence (−1) effectively exists in a site in which SiO₂ is substituted by Al, since +3 Al has entered a site in which +4 valences of Si originally existed. When Si in SiO₂ is substituted by As, a positive 1 valence (+1) effectively exists in a site in which SiO₂ is substituted by As, since +5 As has entered a site in which +4 valences of Si originally existed.

When the additive element A has a valence equal to that of the element M, an effective charge should not seem to be present in an insulating film. However, in a special case, a deep trap level may be formed in a gap in an insulating film consisting of an element M and oxygen, when an additive element M is substituted by the element A. In this case, electrons may be captured by the deep trap level to generate a negative fixed charge. In the Embodiment, the fixed charge using the deep trap level is employed.

The case has been explained, in which an insulating film consists of an element M and oxygen in which the element M is substituted by an additive element A. The explanation is on the assumption that an oxide of the metal M is a base material and atoms A are diffused in the base material.

(Relationship Between Ion Radius of Element Constituting Insulating Film and Ion Radius of Additive Element)

In general, a smaller number of oxygen atoms are easily coordinated to an element having a small ion radius. An ion radius of Si is about 0.4 Å, and four oxygen atoms are coordinated to configure a tetrahedron. In contrast, a larger number of oxygen atoms are easily coordinated to an element having a large ion radius. An ion radius of Hf is about 0.78 Å, and 7 to 8 oxygen atoms are coordinated to configure a calcium fluoride structure. In this case, an element having a small ion radius can be substituted by silicon in an insulating film containing silicon and oxygen, since silicon and oxygen form a tetrahedral structure. However, the material becomes very unstable as an oxide when a material having a large ion radius is substituted by silicon to form a tetrahedral structure. In this case, the element having a large ion radius constitutes a stable state having a large coordination number (larger number of oxygen atoms are coordinated) with oxygen rather than the element is substituted by silicon. This state is silicate.

In an insulating film containing the element M (for example, Hf) having a large ion radius and oxygen, since the element M having the large ion radius and the oxygen form a 6- to 8-coordinate structure, the element M having the large ion radius can be substituted by the additive element A having the large ion radius. However, when the element M having the large ion radius is substituted by an element having a small ion radius to form a 6- to 8-coordinate structure, the element is in a very unstable state as an oxide. In this case, an element itself having the small ion radius constitutes a more stable state with oxygen having a small coordination number (4-coordinate structure) than it is not substituted by the element M having the large ion radius.

A laminate structure is considered having Si substrate/SiO₂ film/high-dielectric-constant film. Here, the high-dielectric-constant film is constituted by an insulating oxide film consisting of the element M having the large ion radius. At this time, when the element A having the large ion radius is added, the element A is likely eccentrically located on the high-dielectric-constant film side. At least a state having a charge can be made eccentric. In contrast, when an element B having a small ion radius is added, the element B is likely eccentrically located on an SiO₂ film side. At least a state having a charge can be made eccentric. By efficiently using the eccentricity, the present inventors devised a method of artificially making a fixed polarization on an interface between the SiO₂ and the high-dielectric-constant film and of controlling a threshold value by the fixed polarization.

The ion radius will be summarized here. In an embodiment of the present invention, the laminate structure having Si substrate/SiO₂ film/high-dielectric-constant film is considered, and the high-dielectric-constant film is considered in which the insulating oxide film consisting of the element M having the large ion radius. In one embodiment of the present invention, it is important that the element to be added is eccentrically located on the SiO₂ film side or the high-dielectric-constant film side in the laminate structure.

As definition of sizes of ion radiuses in one embodiment of the present invention, an ion radius at which a coordination number easily becomes 4 or less is easily formed is a small ion radius, and an ion radius at which a coordination number easily becomes 6 or more is defined as a large ion radius. A theoretical ratio of an ion radius of an ion which makes a 4-coordinate structure with oxygen to an ion radius of oxygen is 0.225, and the ion radius of the oxygen is 1.40 Å. For this reason, the ion radius of the ion which makes a 4-coordinate structure is 0.32 Å. Since a theoretical ratio of an ion radius of an ion which makes a 6-coordinate structure with oxygen to an ion radius of oxygen is 0.414, the ion radius of the ion which makes a 6-coordinate structure is 0.58 Å. This theoretical ratio is described in a large number of textbooks of ceramics (for example, “The chemistry of ceramics” Second Edition by Yanagida Hiroaki (Maruzen Co., Ltd.) P. 12).

When the ion radius is an intermediate value between 0.32 Å and 0.58 Å, i.e., 0.45 Å or less, the ion is expected to form a 4-coordinate structure with oxygen. However, when the ion radius is larger than 0.45 Å and smaller than 0.58 Å, both the 4-coordinate structure and the 6-coordinate structure can be expected to be formed. In the specification, a range from a value larger than 0.45 Å to a value smaller than 0.58 Å is called an intermediate range. An ion radius of an element in the intermediate range is called an intermediate ion radius.

Examples of ion radius will be described below. A number in parentheses denotes an ion radius in an angstrom unit. In the periodic table, it is expected that when an element goes lower, the ion radius of the ion is increased.

The examples are classified as follows;

(a) An element (0.45 Å or less) having a small valence and a small ion radius:

Be (0.33), B (0.22)

(b) An element having a small valence and an intermediate ion radius:

Al (0.49)

(c) An element (0.58 Å or more) having a small valence and a large ion radius:

The element is collectively called as a lanthanide (1.18 to 0.85) such as Mg (0.62), Ca (1.03), Sr (1.21), Ba (1.43), Sc (0.84), Y (0.96) or La and an actinide (1.22 to 0.95) such as Ac.

(d) An element having a large valence and a small ion radius:

P (0.33), As (0.44), S (0.29), Se (0.40)

(e) An element having a large valence and an intermediate ion radius:

V (0.56), Cr (0.49), Te (0.56)

(f) An element having a large valence and a large ion radius:

Nb (0.69), Ta (0.68), Mo (0.62), W (0.62), Sb (0.62), Bi (0.72), Po (0.67)

(g) An element having an equal valence and an intermediate ion radius: Ge (0.5).

An element (Al, Cr, V, Te, or Ge) having an intermediate ion radius can be made eccentric depending on a film forming process. For example, an Al film is formed on SiO₂ film and applied with heat treatment which is sufficient to diffuse Al. Thereafter, a high-dielectric-constant film is formed, thus a large number of Al ions are eccentrically distributed on the SiO₂ film side. However, when an Al film is formed on an SiO₂ film and a high-dielectric-constant film is formed without heat treatment which is sufficient to diffuse Al, and thereafter the resultant structure is applied with heat treatment which is sufficient to diffuse Al, it is understood that Al ions are distributed on both sides of the interface. In this manner, since process dependency occurs, a high-performance transistor can be formed by properly utilizing the process dependency.

Of the elements each having the intermediate ion radiuses, Al and Cr have relatively small radiuses of 0.49 Å, and V and Te have relatively large radiuses of 0.56 Å. As a result, Al and Cr are easily electrically charged on the SiO₂ side and, tend to be distributed as an Al oxide and a Cr oxide but as not electric charges on the high-dielectric-constant film side. More specifically, the elements can be distributed on both sides, i.e., the SiO₂ side and the high-dielectric-constant film side. However, it is understood that the elements are distributed as electric charges on the SiO₂ film side.

When Al is doped in an actual interface between the SiO₂ film and the high-dielectric-constant film to negatively charge the SiO₂ side, an oxygen defect and a fixed polarization of the interface can be formed. This is a mechanism of a threshold shift of pMIS described in Non-patent Document 1. However, the threshold shift is about 200 meV which is insufficient. More specifically, even though, by singularly using an element having an intermediate ion radius and serving as an electric charge on the SiO₂ side, oxygen and a defect are combined to each other to cause threshold shift, thereby a sufficient amount of shift cannot be caused. This is mainly because, in a film forming process, a large number of Al ions are diffused on the high-dielectric-constant film side. That is, when the Al ions are diffused on the high-dielectric-constant film side, some of the Al ions become negative fixed charges. For this reason, a fixed polarization opposite to the above fixed polarization is formed to reduce a magnitude of substantial fixed polarization.

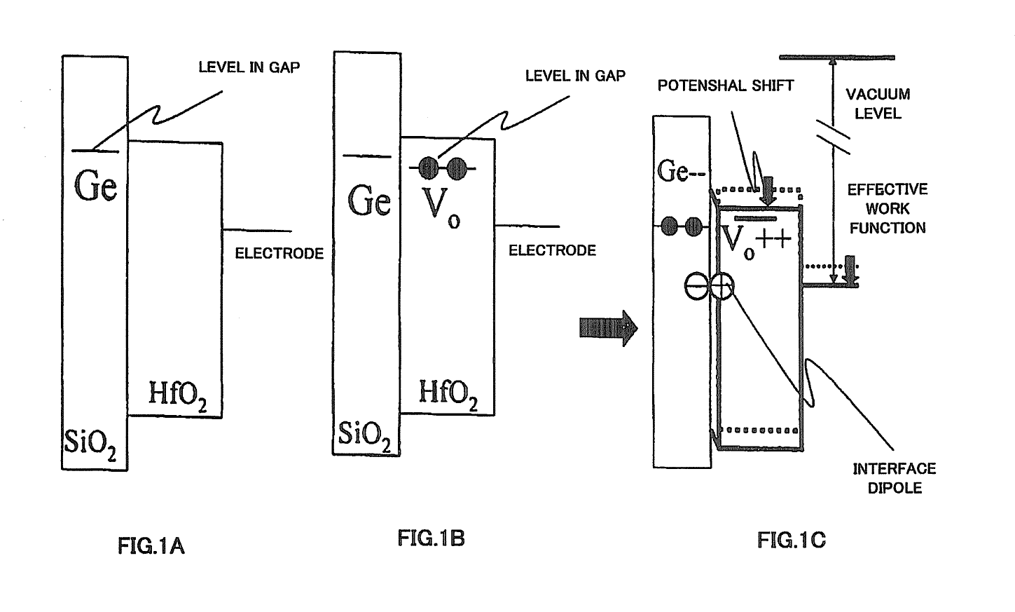

To prevent the drawback, the present inventors propose a method for doping Ge in an interface between the SiO₂ film and the high-dielectric-constant film. FIGS. 1A, 1B and 1C are diagrams for explaining a mechanism which can make interface dipole by doping Ge in the pMISFET according to the embodiment of the present invention.

First, Si is substituted by Ge in the SiO₂ film. It was confirmed by a first principle calculation that Ge is more stable in the SiO₂ film than in the high-dielectric-constant film.

Ge forms a deep trap level in the SiO₂ film (FIG. 1A). That is, Ge can trap electrons in the trap level in the SiO₂ film and can function as a negative charge. In particular, on the interface between the SiO₂ film and the high-dielectric-constant film, oxygen concentrations of the films are different from each other. For this reason, an oxygen defect (Vo) is easily generated by the concentration difference (FIG. 1B). As a result, Ge in the SiO₂ film near the interface receives electrons (FIG. 1C). That is, since electrons which are originally received by oxygen are not received any more, it is understood that Ge in the SiO₂ film near the interface receives the electrons. As a result, Ge functioning as a negative charge and an oxygen defect (Vo) functioning as a positive charge can form a fixed polarization (FIG. 1C). More specifically, on the interface, a negative fixed charge appears on the SiO₂ film side, and a positive fixed charge appears on the high-dielectric-constant film side, so that interface dipole appears. In this manner, as shown in FIG. 1C, an effective work function which is a work function from a vacuum level can be increased, and a large threshold shift can be generated for the pMIS.

On the other hand, although Ge forms a deep trap level in the SiO₂ film, when Ge is separated from the interface, electrons need not be received. For this reason, Ge does not function as a fixed charge. As a result, Ge forms a fixed polarization on only the interface. However, when Ge is separated from the interface and approaches an Si substrate, no fixed charge is generated. In diffusion of Al, since a fixed charge is also generated near the Si substrate, the fixed charge largely influences a channel to deteriorate the mobility. However, when Ge is separated from the interface, the mobility is not deteriorated because Ge does not generate a fixed charge in SiO₂.

Furthermore, Ge does not form a deep trap level in a high-dielectric-constant film. That is, a function as an electric charge need not be considered in the high-dielectric-constant film. As a result, even though a slight amount of Ge is diffused in the high-dielectric-constant film, a polarization opposite to a fixed polarization formed by a negative fixed charge in the SiO₂ film and an oxygen defect on the interface is not formed. As a result, fixed polarizations are not canceled out unlike in use of Al, a sufficiently large fixed polarization can be obtained by only adding Ge.

In particular, when an interface oxygen defect and a fixed polarization are formed, the oxygen defect has a valence of +2, and Ge in the SiO₂ film has a valence of −2. For this reason, fixed polarizations the number of which is four times the number of fixed polarization in case of Al are formed per one additive.

Therefore, Ge has the following large advantages in comparison with Al which is conventionally used. That is, (1) a size of each micro unit of a fixed polarization is four times, (2) an opposite polarization which cancels out does not generate, and (3) Ge does not generate an electric charge in the vicinity of the channel.

However, addition of Ge includes a difficult problem. A high-dielectric-constant film containing a large amount of Ge is a film of poor quality and becomes a leaky film. This is because a structure of Ge and an oxygen defect may be formed or Ge may be diffused out of the high-dielectric-constant film as GeO or the like. As a result, since a large number of oxygen defects are generated in the high-dielectric-constant film, thereby forming a leaky film. More specifically, employing a process or a structure by or with which Ge is diffused in the high-dielectric-constant film to reach an interface between the SiO₂ film and the high-dielectric-constant film, the film quality itself of the high-dielectric-constant film is deteriorated even if the threshold value can be adjusted. As an example of the manufacturing process or the structure, such means proposed as, for example, addition of Ge to a high-dielectric-constant film, forming a GeOx film cap on the high-dielectric-constant film, or use of an SiGe poly electrode.

It is known that when Ge traverses an Si substrate/SiO₂ film interface by diffusion or the like, a large number of interface states are generated to seriously deteriorate MOSFET characteristics (Japanese Journal of applied physics vol. 37 1998, P. 1316). For example, in a Si substrate/SiGe epitaxial film/Si cap/SiO₂ film/high-dielectric-constant film structure or the like, when a large amount of Ge is diffused from SiGe, interfaces between Si substrate/SiGe epitaxial film/Si cap/SiO₂ films are deteriorated. When it comes to the MOSFET characteristics, even though threshold shift occurs, the interfaces are seriously deteriorated, and the deterioration cannot be easily recovered.

In the above example, a fixed polarization is generated between Ge and an oxygen defect. However, it is also possible to form a fixed polarization by doping a large number of positive electric charges (F, Ta, or the like) in an interface or near the interface to make pairs of the electric charges and Ge near the interface. In this case, Ge can be suppressed from being diffused to the high-dielectric-constant film side. This is because F or Ta hinders Ge from being diffused and positive electric charges of F or Ta attract negative Ge.

It is also important that a method of doping a negative electric charge in an interface should be considered to configure a CMIS. When N is doped in an interface, negative electric charges can be obtained. For example, Ge and P are doped in both interfaces of a PMIS and an NMIS, and N is doped in only the interface of the NMIS. In this case, a fixed polarization formed by Ge (−2) and Vo (oxygen defect) (+2) is effected on the PMIS side, and a fixed polarization formed by P (+) and N (−) is effective on the NMIS side.

(Electronic State on Interface Between SiO₂ Film and High-Dielectric-Constant Film)

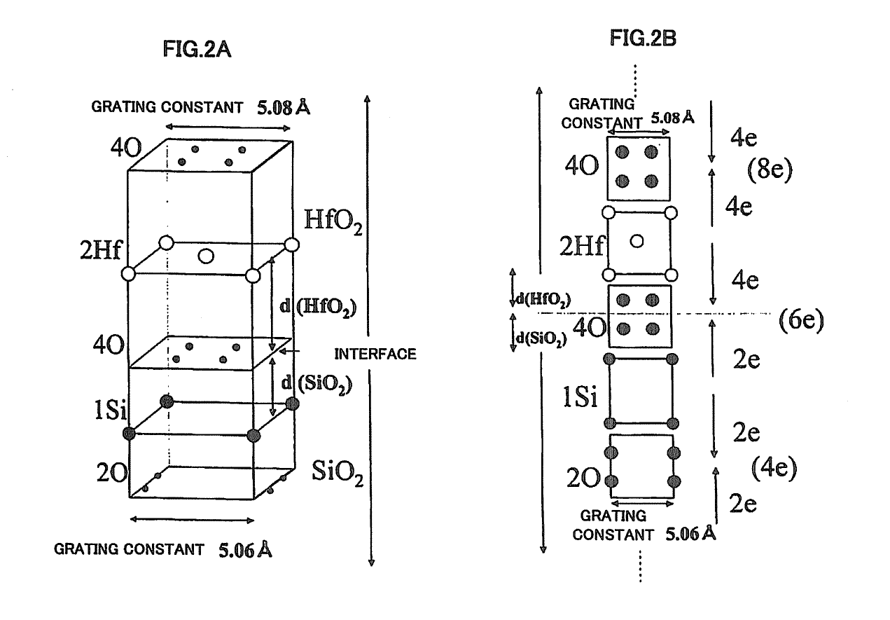

FIG. 2A is a diagram showing an example of structure of an interface between a SiO₂ film and a high-dielectric-constant film. FIG. 2B is a diagram for explaining an electronic state in the interface between the SiO₂ film and the high-dielectric-constant film.

In the interface between the SiO₂ film and the high-dielectric-constant film, different amounts of oxygen are required on the SiO₂ film side and the high-dielectric-constant film side. This is because, generally, optimum oxygen concentration amount changes depending on oxides. As an example of the high-dielectric-constant film, an HfO₂ film will be considered. For example, as shown in FIG. 2B, four electrons are supplied from an HfO₂ film to an interface consisting of oxygen, and two electrons are supplied from a SiO₂ film side. Then, the numbers of electrons are added up. That is, the number of required oxygen ions is four on the HfO₂ film side, and the number of required oxygen ions is two on the SiO₂ film side. According to a structural calculation performed by the present inventors and using the first principle calculation, it is understood that a 4-oxygen-ion structure formed by being filled with an oxygen ion is more stable than a 3-oxygen-ion structure formed by dropping an oxygen ion. Basically, even in the interface, an oxygen defect is a loss in terms of energy. In particular, it can be easily imagined that ions of an element serving as positive electric charges and oxygen ions serving as negative electric charges are present in the high-dielectric-constant film in good proportion is advantageous since the high-dielectric-constant film has an ionic character.

On the other hand, when energy for generating an oxygen defect in the interface is calculated, it is very small. In the interface between the SiO₂ film and the HfO₂ film, an energy which is necessary to generate one oxygen effect is a small value of 0.3 eV with reference to oxygen molecules, i.e., if it is assumed that oxygen emitted to the outside becomes oxygen molecules. Since oxygen defect generation energies in the SiO₂ film or the HfO₂ film are about 5.16 eV and about 6.38 eV (for example, see W. L. Scopel et. al., Applied Physics Letters 84 p1492 2004), it is understood that the oxygen defect generation energy in the interface is smaller than those in the films. The reason for the small oxygen defect generation energy is not only that an oxygen defect is easily generated in the interface but also that the oxygen defects, when they are formed in a film move to the interface and segregates there. In this manner, oxygen defects come to be eccentrically located on the interface, and nothing exists at a position where oxygen having a valence of −2 originally existed. For this reason, a valence of +2 effectively exists.

In the present embodiment, an interface region is defined as follows. If an interface between a SiO₂ film having a thickness of about 5 Å and a high-dielectric-constant film (for example, HfO₂ film) is sufficiently oxidized, the interface seems to be an oxygen surface. This is because the presence of combinations Hf and O and Si and O is more advantageous than the presence of one combination of Hf and Si. This means that a metal is oxidized to be stabilized. The oxygen surface has a same degree of fluctuation as an atomic layer. For this reason, a region including a fluctuation on the interface can be defined by a method using a microscopic image of an SiO₂ film/high-dielectric-constant film interface or using an atom probe (will be described later). The region including the fluctuation on the interface is regarded as an interface region. Estimating the thickness of the interface region as about 7 Å, a center line of the interface region can be regarded as the interface.

(Electronic State Obtained when Fluorine (F) is Doped in Interface)

As described above, in the interface between the SiO₂ film and the high-dielectric-constant film, different amounts of oxygen are required on the SiO₂ film side and the high-dielectric-constant film side. It was understood from the first principle calculation performed by the present inventors that, when fluorine (F) is doped in the interface, an oxygen defect is terminated to obtain a stable structure. Since fluorine has a valence of −1 and substitutes for oxygen having a valence of −2, fluorine may be considered to effectively have a valence of +1. Once fluorine is doped, fluorine is stable and rarely changes in normal semiconductor processes. At the oxygen defect, oxygen moves in or out. However, an interface doped with fluorine is stable.

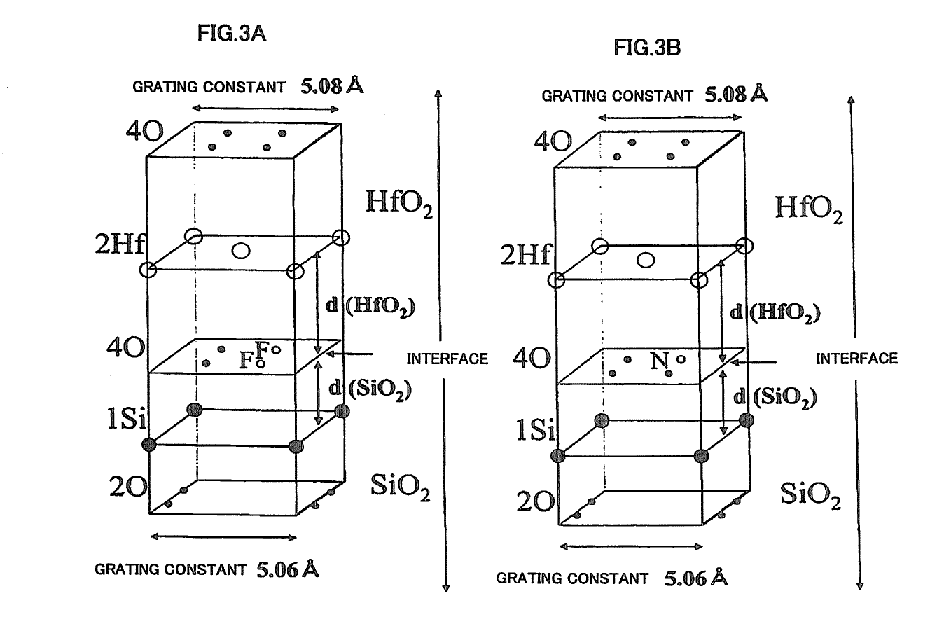

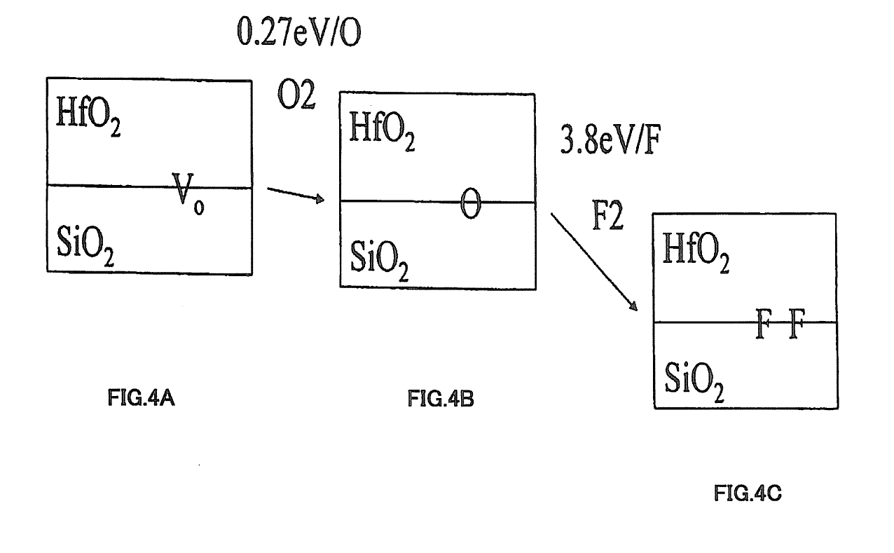

An example of structure in which F is doped in the interface between the SiO₂ film and the high-dielectric-constant film (HfO₂ film) is shown in FIG. 3A. In the interface, two oxygen ions are substituted by fluorine ions. FIG. 4A is a schematic diagram showing a case in which an oxygen defect (Vo) is present in an interface between an SiO₂ film and an HfO₂ film having a stable structure, and shows a state in which an oxygen defect is formed by dropping an oxygen molecule and the number of oxygen molecules in the interface is 3. FIG. 4A shows a state in which oxygen is doped in the state shown in FIG. 4A thereby eliminating an oxygen defect and the number of oxygen molecules in the interface is 4. When one oxygen molecule is doped, energy decreases by 0.27 eV. For this reason, the state shown in FIG. 4B is stable more than the state shown in FIG. 4A. FIG. 4C shows a state in which F is doped in the interface in a state shown in FIG. 4B, thereby substituting F molecules for two oxygen molecules. When F is doped, energy decreases by 3.8 eV per F molecule. For this reason, the state shown in FIG. 4C is much more stable than the state shown in FIG. 4B.

In this manner, stability of an interface between the SiO₂ film and the high-dielectric-constant film changes depending on an amount of oxygen. In particular, although the stability changes depending on the presence/absence of an oxygen defect, a difference between the stabilities is small. However, it is understood that when F is doped from the outside, F selectively substitutes for oxygen in the interface. As shown in FIG. 4C, high stability is exhibited.

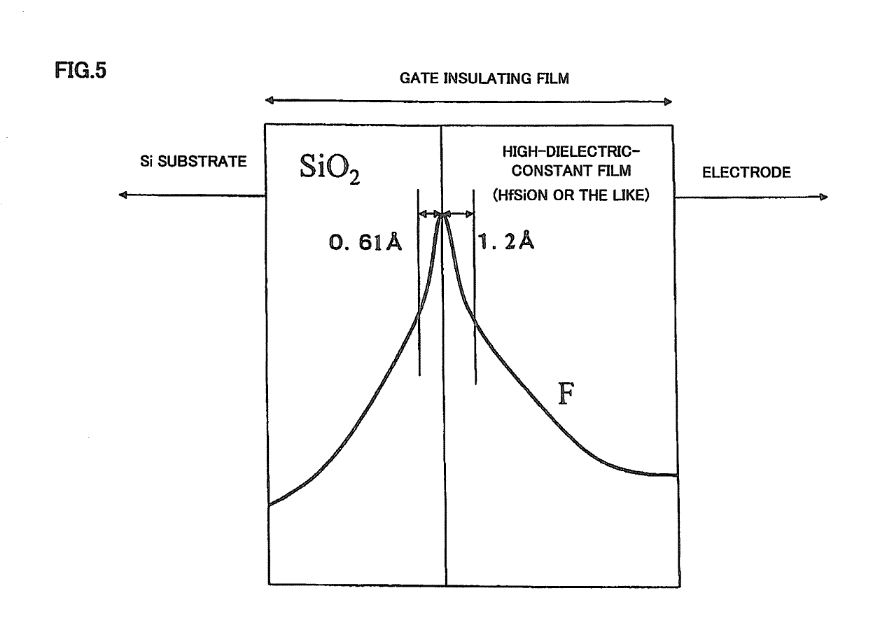

FIG. 5 is a diagram showing a distribution of fluorine in a film thickness direction when fluorine is doped in the interface. As shown in FIG. 5, by addition of F in the embodiment of the present invention, the added F is localized in an interface between an SiO₂ film and a high-dielectric-constant film (for example, HfSiON film). By using a structure in which the localized F forms a fixed positive electric charge required for fixed polarization, a threshold value is controlled. The localized F may be distributed in a range extending from the interface between the SiO₂ film and the high-dielectric-constant film to the SiO₂ film side within 0.61 Å and from the high-dielectric-constant film within 1.2 Å in consideration of a grating interval. A film forming step is devised to make it possible to cause F to have a peak in the interface between the SiO₂ film and the high-dielectric-constant film. In this manner, F in the interface is used as a positive fixed electric charge and can be used as a source of a fixed dipole. In this case, as a scheme of the film forming process, a method is conceivable for doping F in the silicon substrate in advance to supply F to an interface by using thermal diffusion. Since F is stabilized in the interface, a stable structure can be formed when a large amount of F traverses the interface. At this time, since F needs only be diffused and traverse the interface, a high-temperature process at 1050° C. or the like may be used. F in the interface has a configuration which should be discriminated from a configuration of F in a Si substrate or a dielectric material. F in the Si substrate may interact with an n-type dopant in the substrate to form a buried channel. F in the dielectric material film compensates for an oxygen defect to improve a film characteristic of the dielectric material. In particular, a leakage characteristic is improved to strengthen resistance to breakdown.

(Electronic State Obtained when Nitrogen (N) is Doped in Interface)

In an interface between a SiO₂ film and a high-dielectric-constant film, different amounts of oxygen are required on the SiO₂ film side and the high-dielectric-constant film side. It was understood from the first principle calculation performed by the present inventors that, when nitrogen is doped in the interface, an oxygen defect is terminated to obtain a stable structure. However, the structure becomes stable such that nitrogen forms a cluster structure with an oxygen defect. Since nitrogen has a valence of −3 and substitutes for oxygen having a valence of −2, nitrogen may be considered to substantially have a valence of −1. Once nitrogen is doped, nitrogen is stable and rarely changes in normal semiconductor processes. At the oxygen defect, oxygen moves in or out. However, an interface doped with nitrogen is stable.

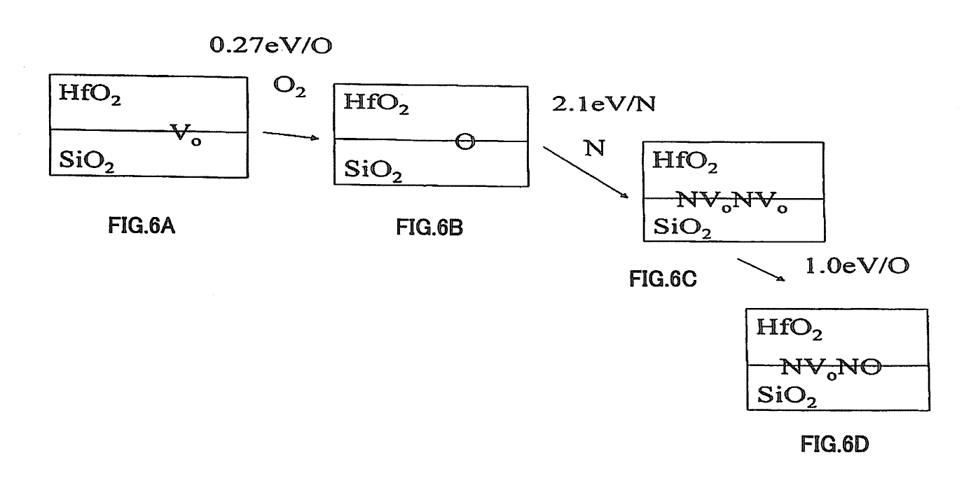

An example of structure in which N is doped in the interface between the SiO₂ film and the high-dielectric-constant film (HfO₂ film) is shown in FIG. 3B. FIGS. 6A, 6B, 6C, and 6D are diagrams showing states in which a system is stabilized by doping N in an interface. FIG. 6A is a schematic diagram showing a case in which an oxygen defect is present in an interface between an SiO₂ film and an HfO₂ film having a stable structure, and shows a state in which an oxygen defect Vo is formed by dropping an oxygen molecule and the number of oxygen molecules in the interface is 3. FIG. 6A shows a state in which oxygen is doped in the interface in the state shown in FIG. 6A, thereby an oxygen defect being eliminated and the number of oxygen molecules in the interface being 4. When oxygen is doped, energy decreases by 0.27 eV. For this reason, the state shown in FIG. 6B is more stable than the state shown in FIG. 6A. FIG. 6C shows a state in which N is doped in the interface in the state shown in FIG. 6B, substituting two N molecules and two oxygen defects Vo for four oxygen molecules. When N is doped, energy decreases by 2.1 eV per nitrogen molecule. For this reason, the state shown in FIG. 6C is much more stable than the state shown in FIG. 6B. FIG. 6D shows a state in which one oxygen defect Vo is substituted by one oxygen molecule in the state shown in FIG. 6C. At this time, when the oxygen defect Vo is substituted by one oxygen molecule, energy decreases by 1.0 eV. For this reason, the state shown in FIG. 6D is much more stable than the state shown in FIG. 6C.

Thus, it is understood that when N is doped from the outside, N selectively substitutes for oxygen in the interface. At this time, high stability is exhibited. A structure in which equal amount of oxygen defects to that of nitrogen molecules are introduced provides a stable state. As shown in FIG. 6D, one of the oxygen defects may be buried with an oxygen molecule. It is understood that the structure is further stabilized when the oxygen defect is buried with oxygen. In any case, it is exhibited that the structure is stabilized by doping nitrogen at a position of the interface of the SiO₂ film and the high-dielectric-constant film.

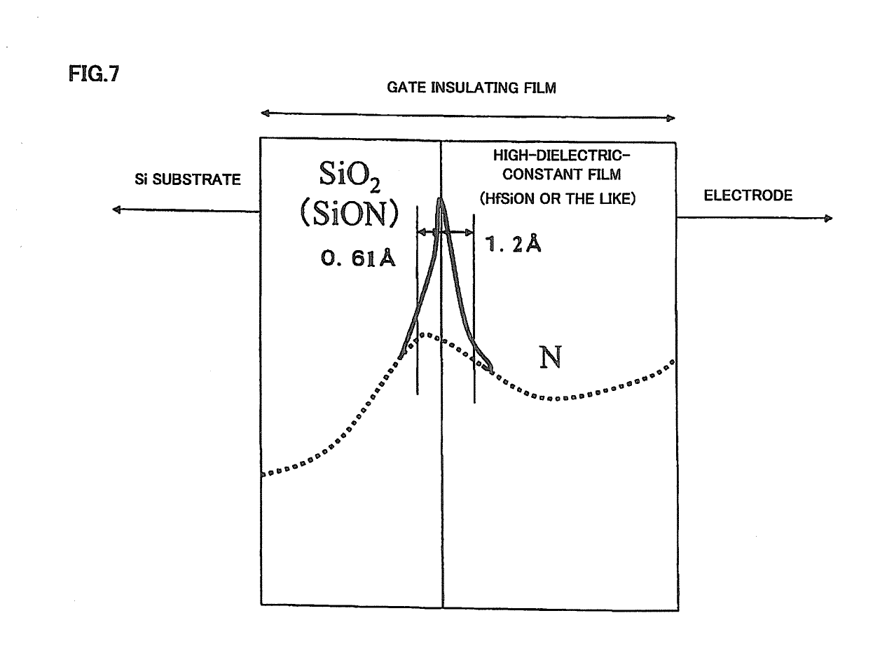

FIG. 7 is a diagram showing a distribution of N in a film thickness direction when nitrogen is doped in an interface. As shown in FIG. 7, the added N is localized in an interface between an SiO₂ film and a high-dielectric-constant film (for example, HfSiON film) in the embodiment of the present invention. The threshold value is controlled by using a structure in which the localized N forms a negative fixed electric charge required for a fixed polarization. More specifically, the localized N may be distributed in a range extending from the interface between the SiO₂ film and the high-dielectric-constant film to the SiO₂ film side within 0.61 Å and to the high-dielectric-constant film side within 1.2 Å in consideration of a grating interval. It is possible to cause N to have a peak in the interface between the SiO₂ film and the high-dielectric-constant film by devising the film forming process. Thus, N in the interface is used as a negative fixed electric charge and can be used as a source of a fixed dipole. In the film forming process, it is possible to dope N in the silicon substrate in advance to supply N to an interface by using thermal diffusion. A stable structure can be formed when a large amount of N traverses the interface, since N is stabilized in the interface. At this time, a high-temperature process at 1050° C. or the like may be used since N only needs to be diffused and to traverse the interface. A process is also effective for doping a large amount of nitrogen in a surface portion of a first insulating film (SiO₂) and then forming a second insulating film (high-dielectric-constant film). In this case, a method for forming a silicon nitride (Si₃N₄) film is possible to dope a large amount of nitrogen. A method is also possible for exposing the surface of the first insulating film to low-temperature (room temperature to about 300° C.) plasma nitrogen or the like. In FIG. 7, a solid-line graph shows a distribution of N near an interface when N is doped in the interface and broken-line graph shows a distribution of N near an interface when N is not doped in the interface. With reference to the drawing, it is understood that nitrogen can be localized in the interface.

(Origin of Fixed Polarization in Interface of SiO₂ Film/High-Dielectric-Constant Insulating Film)

When an oxygen defect is generated in the interface between the SiO₂ film and the high-dielectric-constant film, shortage of electrons occurs compared with the state where oxygen with a valence of −2 is present. More specifically, a valence of +2 seems to be present. As described above, when Ge is doped in the vicinity of the interface, Ge is eccentrically located on the SiO₂ film side, and Ge has a valence of −2 near the interface. When the positive oxygen defect and the negative Ge have directivities, a fixed polarization is formed. Since oxygen defect generation energy is small, oxygen defects are concentrated on the interface. As a result, a positive electric charge (oxygen defect) is present in the interface, and a negative electric charge (Ge) is present in the films, so that the directivity appears because of the presence of the interface. In particular, as a result of the first principle calculation, it is understood that when Ge is eccentrically located from the interface between the SiO₂ film and the high-dielectric-constant film to the SiO₂ film, energy which is larger than that in a case in which Ge is eccentrically located to the SiO₂ film side by 3.5 eV per Ge molecule. As a result, in the interface, a configuration which generates a fixed polarization having a distinct directivity can be formed.

(Amount of an Additive Element)

A fixed polarization configured by a high-dielectric-constant film and an interface will be explained. When a low-valence material is added, the low-valence material serves as a negative electric charge. Oxygen defects the number of which is equal to the number of reduced positive electric charges are formed in the high-dielectric-constant film. Since the oxygen defect serves as a positive electric charge, a polarization can be configured by a combination of the oxygen defect and a low-valence material. In general, since the directivity of a polarization is at random, a polarization does not macroscopically appear. However, when oxygen defects are concentrated on the interface, the directivity appears. As a result, a macroscopic fixed polarization appears.

Even though F (fluorine) is used as a positive electric charge, the same phenomenon as described above occurs. In place of the oxygen defect, F functions as a positive charge. As described above, F is stable in the interface.

High-valence material functions as a positive electric charge when the high-valence material is added. For this reason, a negative electric charge is necessary in order to form a macroscopic fixed polarization. This is possible by adding, for example, nitrogen.

A shift X (volt) obtained by an amount of fixed polarization configured by a high-dielectric-constant film and an interface can be calculated by,

X=(charge area density)×(length of polarization)/dielectric constant. More specifically,
X(volt)=(charge area density)×(length of polarization)/dielectric constant
=(charge area density 1.602×10⁻¹⁹ coulombs×cm⁻²)×(length of polarization×10⁻⁸ cm)/(relative permittivity ∈)/[8.854×10⁻¹² (fard/m)]
=1.81×10⁻⁴ (charge area density cm⁻² unit)×(length of polarization Å unit)/(relative permittivity). For example, when the charge area density is 10¹⁴ cm⁻², the relative permittivity is 20, and a length of polarization is 5 Å,

### X=1.81×10−14×10¹⁴×5/20=0.45 (V).

Here, the charge area density will be briefly explained. The charge area density used here is an effective charge area density. Definition is given as valence difference×area density or an area density (=area density of 2×Ge) of a trap electron when Ge is used. When elements to be added are of a plurality of types, the charge area density is a total sum of valence difference×area density. Since Si, Ti, Zr, or Hf handled in this embodiment is tetravalent, the valence difference is a difference between the valence of the element and the valence of the additive element. It is assumed that an absolute value is used as the valence difference. Specifically, a valence difference between B and Al having valences of III is 1. A valence difference of petravalent V, Nb, Ta, Sb, or Bi is 1, and a valence difference of Mo, W, Te, or Po having a valence of VI is 2. Since differences between oxygen F, N, and an oxygen defect and oxygen are valence differences which are absolute values, the differences are 1, 1, and 2, respectively. For example, when Ge is added to the SiO₂ side, a trap electric charge is −2 when an area density of Ge is given by [Ge]. Hence, a charge area density is 2 [Ge]. When area densities of V. Nb, Ta, Sb, and Bi (valence differences thereof are 1) are given by [V], [Nb], [Ta], [Sb], and [Bi], and when area densities of Mo, W, Te, and Po (valence differences thereof are 2) are given by [Mo], [W], [Te], and [Po], charge area densities are given by [V], +[Nb], +[Ta], +[Sb], +[Bi], +2[Mo], +2[W], +2[Te], and +2[Po], respectively. With respect to N or F, a charge area density is equal to an area density. It may be considered that a positive charge area density and a negative charge area density are equal to each other. A range of error will be described later. The charge area density is given by valence difference×area density. The calculation is performed in consideration of a unit of charge. However, since the charge area density is obtained by only multiplying an area density by a valence difference, it is assumed that the charge area density is described in the same unit as that of an area density here (except for the explanation of the calculating formula) for convenience. Accurately, coulomb·cm⁻² is a unit. However, in order to prevent confusion, it is assumed that the description is made without a coulomb unit.

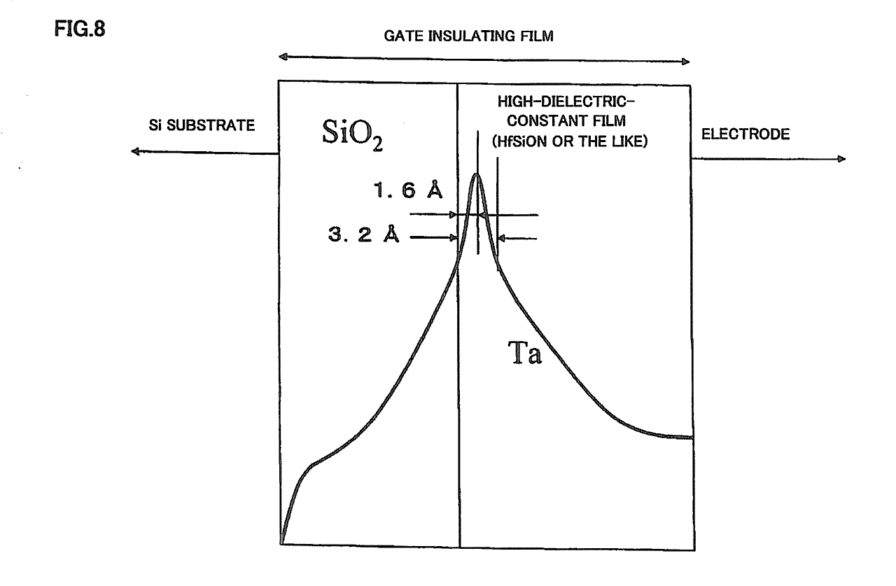

A peak position of a distribution of an additive element on a high-dielectric-constant film (for example, HfSiON film) side will be described below. On the high-dielectric-constant film, a normal length of polarization is about 1.38 Å, and a dielectric constant is about 20. In this case, 1.38 Å is a typical distance of a metal constituting a high-dielectric constant material from an interface. When an error of the distance is set to 15%, and an error of an interface position is set to 15%, a distance from the interface is 1.4 Å±0.2 Å (see FIG. 8). FIG. 8 shows a distribution of an element such as Ta having a large ion radius in a film thickness direction of a laminated film consisting of an SiO₂ film and a high-dielectric-constant film when the element is added in an interface. Therefore, the distance of a peak position from the interface is 1.6 Å or less.

In consideration of an error of experiment, the length of the peak position from the interface is considered to be twice 1.6 Å, i.e., 3.2 Å or less. When the number of bonds between the element such as Ta having a large ion radius and oxygen is large, the element is more stable in the interface between the SiO₂ film and the high-dielectric-constant film. For this reason, the film forming process is devised to make it possible to cause the element to have a peak eccentrically located on the high-dielectric-constant material side with reference to the interface. In this manner, the element such as Ta having a large ion radius is used as a positive fixed electric charge and can be used as a source of a fixed dipole.

A charge area density of an additive element on the high-dielectric-constant film (for example, HfSiON film) side will be considered below. Since an amount of polarization of 0.5 V to about 1.0 V is necessary to adjust a threshold value of a pMISFET, a necessary charge area density is about 4.0×10¹⁴ cm⁻² to 8.0×10¹⁴ cm⁻². This numerical value is obtained from the following equation. More specifically, since 1.81×10⁻¹⁴ (8×10¹⁴)×1.38/20=1.0 (V), a maximum value of 8.0×10¹⁴ cm⁻² is obtained. Depending on a type of a high-dielectric-constant film material, each of a magnitude of polarization and a magnitude of a dielectric constant has a margin of about 30%. For this reason, in consideration of the margin of 60% as a whole, the charge area density may be considered to be about 2.4×10¹⁴ cm⁻² to 1.3×10¹⁵ cm².

As is typically shown in FIG. 8, a distribution of the element in the thickness direction can be approximately understood by SIMS (Secondary Ion Mass Spectroscopy), XPS (X-ray Photoelectron Spectroscopy), or the like. However, in recent years, a method (atom probe method) of cutting an SiO₂ film/interface region/high-dielectric constant film in a rod-like shape to measure a detailed three-dimensional distribution by an electric field evaporation. According to this method, a manner of localizing atoms in an interface or the like can be measured with a resolution higher than that of a conventional method. Since the method of evaporating atoms in units of layers is used, a distribution of atoms in each layer can be theoretically measured. The resolution may be considered to be performed in an atomic layer order.

Summarizing above description, a charge area density obtained by a material (i.e., element having a large ion radius) serving as an electric charge on the high-dielectric-constant film is preferably about 2.4×10¹⁴ cm⁻² to 1.3×10¹⁵ cm⁻², and is more preferably 4.0×10¹⁴ cm⁻² to 8.0×10¹⁴ cm⁻². A material with a valence of ±1 serving as an electric charge has a charge area density which is equal to an amount of material. However, it should be noticed that a material with a valence of ±2 has a charge area density which is twice an amount of material. When materials serving as electric charges of a plurality of types are doped, a total sum of charge area densities of the materials preferably satisfies the above range. As one characteristic of a high-dielectric-constant film, a large number of electric charges are required because the high-dielectric-constant film has a high dielectric constant. When TaN of one layer is formed near an interface, about 4.0×10¹⁴ Ta atoms and N atoms are necessary. A TaN film having a film thickness of about 1.4 Å is formed, and an HfSiON film is formed thereon. In this case, the above structure can be realized.

(Equality Between Positive Charge Area Density and Negative Charge Area Density)

When an amount of Ta and an amount of N are considered, the amounts are preferably equal to each other. This is because, since a polarization is formed and both valence differences of the materials are 1, the area densities are preferably equal to each other. The above optimum range is defined in a condition in which a shift amount secures 0.5 to 1.0 V. In order to define an actual shift amount, when the shift amount is about 0.05 V according to a profile of channel dope or the like, the shift amount can be finely adjusted. Therefore, an error of about 10% of the minimum value does not pose a problem. Therefore, a difference between the amount of Ta and the amount of N is desirably 10% or less of a minimum value of a charge area density (=valence difference×area density), i.e., a lower-limit value of each case. As in the subsequent description, a charge area density of a positive electric charge and a charge area density of a negative electric charge are desirably equal to each other. When the difference therebetween is suppressed to about 10% of the minimum value of the charge area density, any problem is not posed.

More specifically, since it is understood that, on the high-dielectric-constant film, a charge area density obtained by a material (i.e., element having a large ion radius) serving as an electric charge is preferably 2.4×10¹⁴ cm⁻² to 1.3×10¹⁵ cm⁻², and more preferably 4.0×10¹⁴ cm⁻² to 8.0×10¹⁴ cm⁻². It is understood according to the lower limits that, as differences between positive charge area densities and negative charge area densities are preferably 2.4×10¹³ cm⁻² or less and 4.0×10¹³ cm⁻² or less, respectively. More specifically, the difference is preferably 4.0×10¹³ cm⁻² or less, and more preferably 2.4×10¹³ cm⁻² or less.

In the following description, it is assumed that the maximum value of the difference is defined as 10% of the lower-limit value of an appropriate range of the charge area density.

A peak position of a distribution of an additive element on the SiO₂ film side and an optimum value of the charge area density of an additive will be described below.

As has been described above, it is understood that Ge is an element having an intermediate ion radius and is considerably eccentrically located on the SiO₂ film side. In addition, Ge traps electrons near the interface to be a fixed electric charge having a valence of −2.

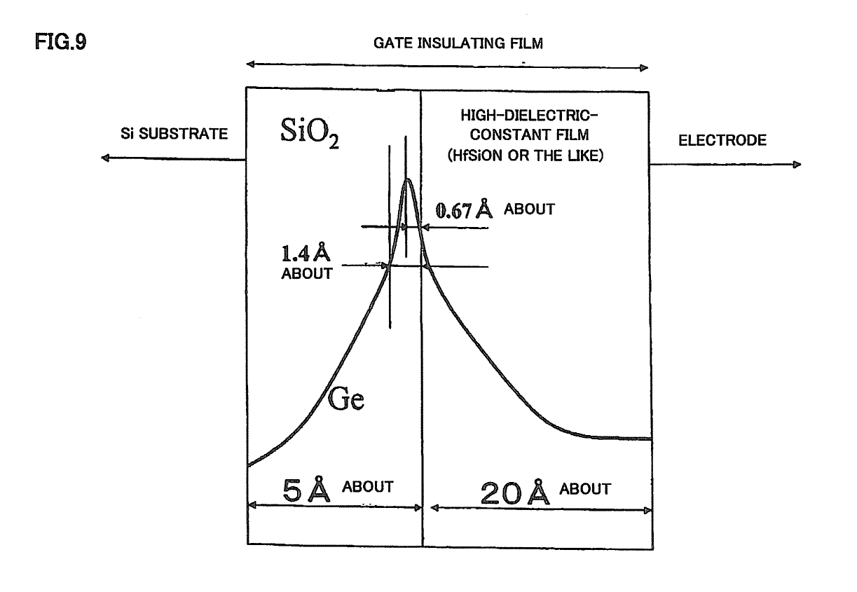

On the SiO₂ film side, a length of normal polarization is small, i.e., about 0.64 Å. The length of polarization includes an error of about 10%. More specifically, the length of polarization is 0.64±0.03 Å (FIG. 9). FIG. 9 shows a distribution of an element such as Ga (or element such as P or As having a small ion radius) in a film thickness direction of a laminated film consisting of an SiO₂ film and a high-dielectric-constant film when the element is added in an interface. A peak position of Ge is 0.64±0.03 Å when an interface position and a peak position have errors of ±5%. Therefore, a distance of the peak position from the interface is 0.67 Å or less on the SiO₂ film side. In consideration of an error of an experiment, the distance is considered to be less than 1.4 Å which is about twice 0.67 Å.

Since an amount of polarization of 0.5 V to about 1.0 V is necessary to adjust a threshold value of a pMISFET transistor, a necessary charge area density is about 1.7×10¹⁴ cm⁻² to 3.4×10¹⁴ cm⁻². Depending on a type of a high-dielectric-constant film material (method of forming an SiO₂, or SiON obtained by doping nitrogen), each of a length of polarization and a magnitude of a dielectric constant has a margin of about 10%, and a total margin is about 20%. For this reason, the charge area density may be considered to be about 1.4×10¹⁴ cm⁻² to 4.1×10¹⁴ cm⁻².

Summarizing above description, a charge area density obtained byamaterial (i.e., Ge or an element having a small ion radius) serving as an electric charge on the SiO₂ film is preferably about 1.4×10¹⁴ cm⁻² to 4.1×10¹⁴ cm⁻² and is more preferably 1.7×10¹⁴ cm⁻² to 3.4×10¹⁴ cm⁻².

Since the value is a charge area density, 2×(area density of Ge) falls within the range for an element such as Ge having a valence of −2. More specifically, (area density of Ge) is preferably 0.7×10¹⁴ cm⁻² to 2.1×10¹⁴ cm⁻². Furthermore, the area density is more preferably 0.85×10¹⁴ cm⁻² to 1.7×10¹⁴ cm⁻².

Here, it is assumed that a maximum value of a difference between amounts of charges when positive electric charges and negative electric charges are introduced are determined as 10% of the lower-limit value of the appropriate range of the charge area density. It is understood that differences between the lower limits of the appropriate ranges and the positive charge area density and the negative area density are preferably 1.4×10¹³ cm⁻² or less and 1.7×10¹³ cm⁻² or less, respectively. More specifically, the differences are preferably 1.7×10¹³ cm⁻² or less and more preferably 1.4×10¹³ cm⁻² or less.

A material with a valence of ±1 serving as an electric charge has a charge area density which is equal to an amount of material. However, it should be noticed that a material with a valence of +2 has a charge area density which is twice an amount of material. When materials serving as electric charges of a plurality of types are doped, a total sum of charge area densities of the materials preferably satisfies the above range.

(Case in which Polarization is Generated by Electric Charge on High-Dielectric-Constant Film Side and Electric Charge on Sio₂ Film Side)

When polarization is generated by the electric charge on the high-dielectric-constant film and the electric charge on the SiO₂ film, the polarization is generated as a sum of both the electric charges. On the high-dielectric-constant film side, a magnitude of polarization is about 1.38 Å, and a dielectric constant is about 20. On the SiO₂ film side, a magnitude of normal polarization is small, i.e., about 0.64 Å. A dielectric constant is about 4. Since an amount of polarization of 0.5 V to about 1.0 V is necessary to adjust a threshold value of a p-type MISFET, a necessary charge area density is about 1.2×10¹⁴ cm⁻² to 2.4×10¹⁴ cm⁻². Depending on a type of a high-dielectric-constant film material, the dielectric constant can be changed within about 30%. Depending on a type of a SiO₂ film material (method of forming an SiO₂, or the type obtained by doping nitrogen such as SiON), a magnitude of the dielectric constant has a margin of about 20%. For this reason, the amounts of charge on both the high-dielectric-constant film side and SiO₂ film side may be equal to each other and can be considered to be about 1.0×10¹⁴ cm⁻² to 3.0×10¹⁴ cm⁻².

Summarizing above description, charge area densities obtained by materials (i.e., an element having a large ion radius on the high-dielectric-constant film side, and Ge or an element having a small ion radius) serving as electric charges on both the sides of the interface between the high-dielectric-constant film and the SiO₂ film are well equal to each other (charge compensation) on the high-dielectric-constant film side and the SiO₂ film side, and are preferably about 1.0×10¹⁴ cm⁻² to 3.0×10¹⁴ cm⁻². Furthermore, the charge area densities are more preferably 1.2×10¹⁴ cm⁻² to 2.4×10¹⁴ cm⁻². Here, it is assumed that a maximum value of a difference between amounts of charges when positive electric charges and negative electric charges are introduced are determined as 10% of the lower-limit value of the appropriate range of the charge area density. It is understood that differences between the lower limits of the appropriate ranges and the positive charge area density and the negative area density are preferably 1.0×10¹³ cm⁻² or less and 1.2×10¹³ cm⁻² or less, respectively. More specifically, the differences are preferably 1.2×10¹³ cm⁻² or less and more preferably 1.0×10¹³ cm⁻² or less.

Since an amount of polarization of about 0.3 V is sufficient to adjust a threshold value of an n-channel MISFET, an amount of electric charge which is about 30 of the optimum value obtained when various p-channel MISFETs are configured may be used.

(Polarization Forming Pattern by Fixed Electric Charge)

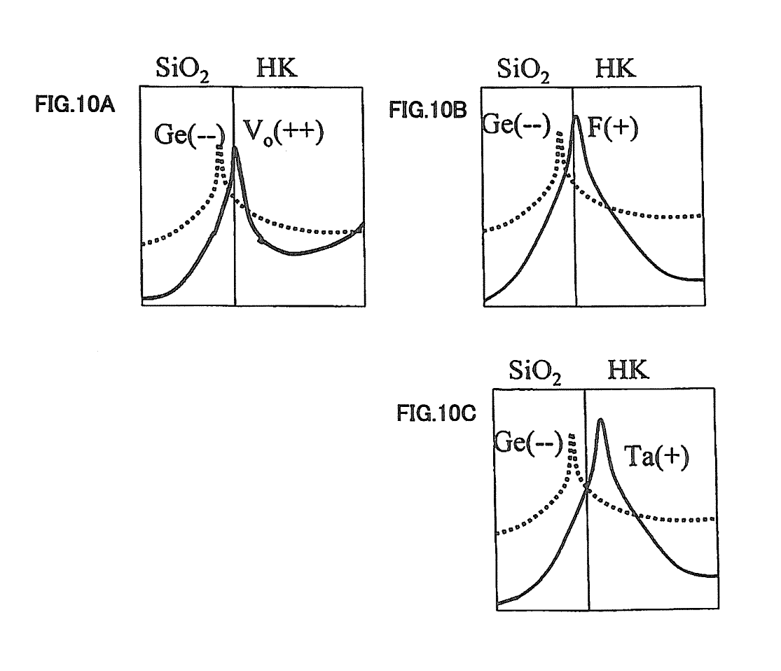

A polarization forming pattern by a fixed electric charge will be described below with reference to FIGS. 10A to 10C with respect to a pMISFET. In order to form a fixed polarization in an interface, as an origin of a positive electric charge,

1) a method for supplying a large number of oxygen defects (FIG. 10A)
2) a method for using fluorine which is stable in an interface and stably substituted by oxygen (FIG. 10B), or
3) a method for doping a high-valence material (FIG. 10C)
can be considered.

In contrast, as an origin of a negative electric charge,

a method for doping Ge (eccentrically located on the SiO₂ film and traps electrons near the interface) (FIGS. 10A, 10B, and 10C) can be considered.

In this manner, the distribution patterns of the positive and negative charges shown in FIGS. 10A to 10C, in a pMISFET, a fixed polarization having a negative electric charge on a channel side and a positive electric charge on an electrode side can be formed. By using the fixed polarization, an effective work function of an electrode can be made deep (large). The effective work function can be selected as about 5.0 eV, and a threshold value of a pMIS can be decreased.

A polarization forming pattern in an nMISFET by a fixed electric charge can be similarly considered. In order to form a fixed polarization in an interface, as an origin of a positive electric charge, an oxygen defect in an interface, fluorine in an interface, and a high-valence material are conceived. In contrast, interface nitrogen and a low-valence material can be conceived. In an nMISFET, a fixed polarization having a positive electric charge on a channel side and a negative electric charge on an electrode side is formed to make it possible to make an effective work function of an electrode shallow (small). The effective work function can be selected as about 4.1 eV, and a threshold value of an nMIS can be decreased.

(Thin Film Growing Mode)

In an embodiment of the present invention, by depositing Ge, a Ge oxide (GeOx) or a metal germanide (TaGe or the like) on an interface between an SiO₂ film and a high-dielectric-constant film, a fixed polarization is artificially formed near the interface between the SiO₂ film and the high-dielectric-constant film. It is known that the processes of depositing materials on a substrate are roughly classified into the following three forms. Classification A: three-dimensional nucleation (Volmer-Wever type), classification B: single-layer growth (Frank-van der Merwe type), and classification c: on-single-layer nucleation (Stranski-Krastanov type).

Classification A is a process in which a metal (or a metal oxide or a metal germanide) aggregates on the SiO₂ film to form a nucleus and a metal flied from a deposition source collects at the nucleus, thereby growing three-dimensionally. A lot of methods for forming a thin film are classified in this type. This type is a kind of island growing pattern. For example, when a metal La is deposited on a SiO₂ film, it is understood that a nucleus is three-dimensionally grown. In the deposition of Ge (as well as a Ge oxide or a metal germanide) used in an embodiment of the present invention is considered to be classified in this type of growing pattern.

Classification B is a type which easily occurs when an interaction between the SiO₂ film and a metal (or a metal oxide or a metal germanide) is strong. In a film growing pattern, two-dimensional phases are laminated one by one to form a thin film. This corresponds to atomic layer growth (Atomic Layer Deposition) or the like of a metal oxide using an oxidant. At the present, atomic layer growth of Al₂O₃ or the like is realized. The growth of a metal oxide used in an embodiment of the present invention can be considered to be able to realize a pattern of the atomic layer growth in the future.

Classification C is a type which occurs when an interaction between the SiO₂ film and a metal (or a metal oxide or a metal germanide) and an interaction between the metals are also strong. As in Classification B, a thin film as an atomic layer level is formed, and a three-dimensional nucleus is generated by an interaction between the metals on the thin film. A pattern occurs in a very limited case in which an island is grown on a film grown.

The growth modes can be discriminated from each other such that a metal (or a metal oxide or a metal germanide) which is actually deposited on an SiO₂ film while changing an amount of deposition is observed with an electron microscope, an STM, or the like. On the SiO₂ film, since the metals (or metal oxides or metal germanides) have a large interaction, a mode (Classification A) in which a nucleus is formed is a main mode. In the future, it is considered that atomic layer growth of a large number of metal oxides will be realized.

When a sputtering method is used as a method of depositing a material including Ge, the metal can be sputtered on the SiO₂ side, and a structure of the present application can be more easily realized.

As an embodiment of the present invention, a method of manufacturing a field effect transistor and a structure thereof will be described below.

### Example 1

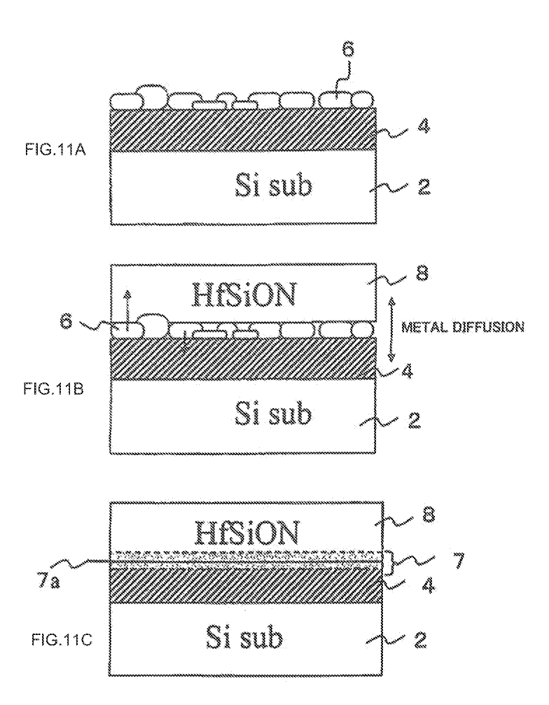

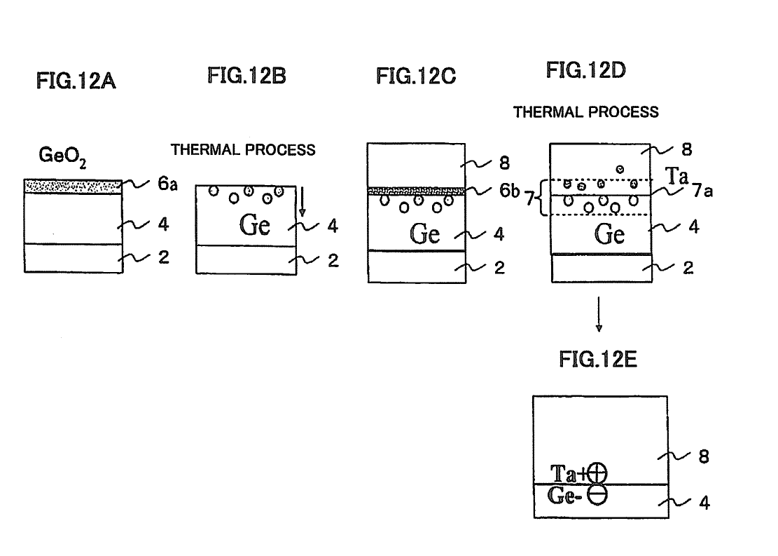

A pMISFET according to the first example of the present invention will be described below with reference to FIGS. 11A to 12D. FIGS. 11A, 11B, and 11C are schematic diagrams for explaining a method for manufacturing of a pMISFET according to the first embodiment of the preset invention.

The pMISFET according to the example is formed on an n-type silicon substrate 2 by the following steps. The pMISFET has a laminated structure including a silicon substrate 2, an SiO₂ film 4 and a high-dielectric-constant film 8.

As shown in FIG. 11A, the SiO₂ film 4 is formed on the silicon substrate 2. Then, Ge, Ge oxide, or a metal germanide 6 is deposited on the SiO₂ film 4. At this time, island growth occurs. As shown in FIG. 11B, the high-dielectric-constant film 8 is deposited on the deposit 6 of the Ge, a Ge oxide, or a metal germanide. Thereafter, as shown in FIG. 11C, the deposit 6 is diffused in the SiO₂ film 4 or the high-dielectric-constant film 8. At this time, the Ge, a Ge oxide, or a metal germanide is diffused in an interface region 7 between the SiO₂ film 4 and the high-dielectric-constant film 8. A center line of the interface region 7 is shown as an interface 7a. As has been described above, it is understood from our first principle calculation that a Ge atom is stable on the SiO₂ film 4 side. During formation of the high-dielectric-constant film 8 shown in FIG. 11B, the deposit 6 may be diffused in the SiO₂ film 4 or the high-dielectric-constant film 8. The diffusing step of the deposit 6 in the SiO₂ film 4 may be performed after the deposit 6 shown in FIG. 11A is deposited and before the high-dielectric-constant film 8 is formed.

The high-dielectric-constant film used in the example is an HfSiON film. The HfSiON film is formed such that, the HfSiO film is nitrided from a front surface side using plasma nitriding at a room temperature (20° C.) for 30 seconds after an HfSiO film is formed by a CVD method (in this case, 260° C.). Here, the temperature and the time are adjusted as described above such that Si amount/(Hf amount+Si amount)=0.25 and N amount/(O amount+N amount=0.2 are satisfied. However, the Si amount or the N amount are not essential in the example and are only an example. Therefore, a conventional high-dielectric-constant film may be directly used. It is an object of the example to provide a MIS device having a low threshold value by adding some step to the conventional steps.

For the high-dielectric-constant film, an oxide film of Hf, Zr or Ti (HfO₂, ZrO₂, or TiO₂), a silicate film thereof (HfSiO, ZrSiO, or TiSiO), a nitride film thereof (HfOn, ZrON, TiON, HfSiON, ZrSiON, or TiSiON) or the like can be used. A laminated film (HfON/HfSiON/TiON film or the like) of the above films can also be used. Since an (Hf or Zr) O₂ mixed-crystal film, a nitride film (Hf or Zr) ON thereof or a silicate HfZrSiO or HfZrSiON thereof is maintained even though an amorphous state at a high temperature (for example, annealing in N2 at 1050° C. or the like), these films are effectively used. Furthermore, an oxide, an oxynitride, or the like having a perovskite structure (SrTiO₃, SrZrO₃, SrHfO₃, or the like) or a pyrochlore structure (La₂Zr₂O₇, La₂Hf₂O₇, Y₂Zr₂O₇, Y₂Hf₂O₇, or the like) is promising. In this case, a tetravalent element Hf, Zr, or Ti is selected as a constituent element of a high-dielectric-constant material. This is because the oxide film has important characteristics, i.e., high thermal stability and a high dielectric constant. An essential of the exemplary embodiment is that, in the interface between the SiO₂ film and the high-dielectric-constant film, an additive has an eccentric distribution to generate a fixed polarization. In this sense, it is important that Hf, Zr, and Ti are elements each having a large ion radius. A tetravalent material having a valence equal to that of Si is significantly considered. When the valence of the additive is 2, 3, 5, or 6, an electric charge distribution can be controlled depending on an eccentric position, i.e., whether the additive is eccentrically located on the SiO₂ film side or the high-dielectric-constant film side. Although Ge is a tetravalent element, a calculation result which forms a deep level of an electron trap near the interface on the SiOs film in the SiO₂ film/high-dielectric-constant film interface is also important. Since substitution between the tetravalent elements is performed, in bulk, normally an excessive electric charge is not normally generated. However, only near the interface on the SiO₂ film, a negative electric charge is generated.

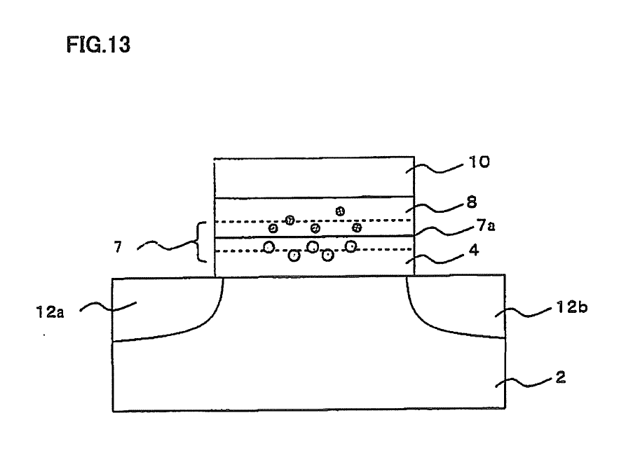

Details of a method of manufacturing a pMISFET according to the example will be described below with reference to FIGS. 12A to 12D and FIG. 13.

As shown in FIG. 12A, the SiO₂ film 4 having a thickness of 0.5 nm is formed on the n-type silicon substrate 2 by thermal oxidation. Also in the following examples, unless otherwise noted, the SiO₂ film 4 on the silicon substrate 2 is defined as a thermal oxide film having a thickness of 0.5 nm described here. A GeO₂ film 6a having a thickness of 0.3 nm is formed on the SiO₂ film 4 as a first metal oxide film. Thereafter, the resultant structure is applied with an annealing process at 600° C. for 10 seconds in an atmosphere of a gas mixture of Ar and nitrogen. In this step, Ge is diffused in the SiO₂ film 4 (FIG. 12b)

As shown in FIG. 12C, a laminated structure of a Ta₂O₅ film 6b having a thickness of 0.3 nm as a second metal oxide and an HfSiO film serving as a high-dielectric-constant film having a thickness of 2 nm is formed. Thereafter, the HfSiO film is changed into an HfSiON film 8 by plasma nitriding. The HfSiON film 8 has a dielectric constant of about 20 and a film thickness of 2 nm which corresponds to an equivalent oxide thickness EOT of 0.4 nm. Also in the following example, unless otherwise noted, an HfSiON film is used as the high-dielectric-constant film 8.

Thereafter, as shown in FIG. 12d, the resultant structure is applied with an annealing process at 1050° C. for 5 seconds in an atmosphere of a gas mixture of nitrogen/oxygen/Ar to form the interface region 7 shown between the SiO₂ film 4 and the HfSiON film 8. The interface region 7 is a region including the interface 7a between the SiO₂ film 4 and the HfSiON film 8. An amount of oxygen in the gas mixture atmosphere in the annealing process does not have a large dependency. According to a test result obtained after the pMISFET of the example is formed, it was understood that a shift characteristic of a threshold voltage of the pMISFET does not change while O₂ amount/(N₂+O₂+Ar) amount ranges 0.1% to 5%. However, the amount of oxygen is smaller than 0.1%, the reliability of the HfSiON film is deteriorated. Specifically, the threshold value largely varies while applying a voltage to a gate electrode, when a change with time is observed. That is, when annealing is performed in a gas mixture atmosphere including oxygen at 0.1% or more, a shift amount of the threshold voltage is 10 mV or fewer in 10 hours. However, when annealing is performed in a gas mixture atmosphere free from oxygen or when annealing is performed in a gas mixture atmosphere including a small amount of oxygen at 0.1% or less, it was observed that the shift amount of the threshold value exceeds 100 mV.

As shown in FIG. 13, a gate electrode 10 having a laminated structure containing TiN and W is deposited. Thereafter, the gate electrode 10, the HfSiON film 8, interface region 7 and the SiO₂ film 4 are patterned to form a gate. By using the gate as a mask, a p-type impurity is doped in the silicon substrate 2 to form a p-type source region 12a and a drain region 12b to form a pMISFET. In this embodiment, W having good processability is selected as the gate electrode 10 to take a contact. However, a conductive polysilicon or the like may be used.

Distributions of germanium and tantalum in a film thickness direction in the pMISFET formed as described above were examined. As a result, a large amount of Ge is diffused in the SiO₂ film 4 in the interface and serves as a negative electric charge. According to a measurement result by SIMS, the distribution of Ge has a peak near the interface in the SiO₂ film 4, i.e., at a position having a distance of about 0.64 Å from the interface, and has an area density of about 0.75×10¹⁴ cm⁻². Ta is diffused on the interface side of the high-dielectric-constant film (HfSiON) 8 and serves as a positive electric charge. According to the measurement result by SIMS, the distribution of Ta has a peak near the interface in the HfSiON film, i.e., at a position having a distance of about 1.4 Å from the interface, and has an area density of about 1.5×10¹⁴ cm⁻². That is, at this time, an area density is twice that of the Ge amount. This is because Ge traps an electron to have a valence of −2 and, since Ta has a valence of +1, a Ta twice as much as Ge is required.

That is, in the embodiment, as shown in FIG. 12E, in the laminated structure of the SiO₂ film and the high-dielectric-constant film, a negative electric charge is generated on the SiO₂ film 4 side, and a positive electric charge is generated on the high-dielectric-constant film 8 side. A fixed polarization formed by the fixed electric charges changed a flat band voltage by about 650 mV, and an effective work function of the gate electrode was 5.07 eV. A characteristic in which area densities of Ge and Ta are equal to each other was observed here. Ge serves as an electric charge on the SiO₂ film side, and Ta serves as an electric charge on the HfSiON film side. In contrast, Ge tends not to be present as an electric charge but to be present as an oxide thereof on the HfSiON film side, and Ta tends not to be present as an electric charge but to be present as an oxide thereof on the SiO₂ film side. That is, Ge is present as GeO₂ on the HfSiON film side, and Ta is present as Ta₂O₅ on the SiO₂ film side. According to this characteristic, excessive Ge and metal Ta are not present in the stable state as electric charges, and compensation of the electric charges may occur. As a result, the area densities of the electric charges of Ge and Ta may be equal to each other.

In this manner, since the compensation of electric charges occurs, the number of isolated electric charges (electric charges which are not compensated for) in the interface is very small. This phenomenon can be easily understood such that a way of a change in flat band voltage is observed by changing a film thickness of the HfSiON film. This is because, when a shift amount of the flat band voltage has a tendency depending on the film thickness, the tendency is considered to be an amount of uncompensated electric charge.

In the embodiment, it is important that a large amount of Ge is diffused on the SiO₂ film 4 side of the interface and serves as a negative electric charge and Ta is diffused on the high-dielectric-constant film 8 side and serves a positive electric charge. The electric charges are distributed across the interface such that negative charge is distributed on the channel side and positive charge is distributed on the electrode side having directivity in the film thickness direction. Thus a large fixed polarization is formed since large amounts of electric charges having an opposite polarity are present across the interface having a long distance between them. For this reason, a required amount of additive is advantageously small. In particular, when an additive which forms a fixed electric charge enters the SiO₂ film (Ge in the example), a number of electric charges near the channel are preferably minimized. With respect to this point, the configuration which can reduce an amount of additive is advantageous.

Variation 1 of Example 1 will be described below. (Variation 1)

In Variation 1, the annealing process in the processes for manufacturing the pMISFET according to Example 1 is omitted, which is performed at 600° C. for 10 minutes in an atmosphere of a gas mixture of Ar and nitrogen after the GeO₂ film 6a is formed is. More specifically, the SiO₂ film 4 having a film thickness of 0.5 nm is formed on the silicon substrate 2 by thermal oxidation. Thereafter, a first metal oxide which is the GeO₂ film 6a having a film thickness of 0.3 nm is formed on the SiO₂ film 4. A laminated structure having a second metal oxide which is the Ta₂O₅ film 6b having a film thickness of 0.3 nm and an HfSiO film serving as a high-dielectric-constant film and having a film thickness of 2 nm is formed. Thereafter, the HfSiO film is changed into the HfSiON film 8 by plasma nitriding. Thereafter, the resultant structure is applied with an annealing process at 1050° C. for 5 seconds in an atmosphere of a gas mixture of nitrogen/oxygen/Ar.

In Variation 1, since Ge is diffused only in the SiO₂ film 4 at the interface by a thermal process, a sufficient amount of Ge (i.e., a negative electric charge) can be secured in the SiO₂ film 4. Although Ge is an element having an intermediate ion radius, Ge is extremely stabilized in the SiO₂ film 4.

For example, it is understood that an element such as Al having an intermediate ion radius are diffused into both sides in the interface region. However, only Ge is an exception and is localized almost in the SiO₂ film 4. Al serves as a negative electric charge in the SiO₂ film 4 and can be used for threshold adjustment for a pMIS. Al tends to also enter the high-dielectric-constant film (HfSiON) side. Although Al is desired to be eccentrically located on the SiO₂ film side, Al enters the HfSiON side. Thus, an amount of Al becomes insufficient. A most of the aluminum in the HfSiON film is present as Al₂O₃ or in a state called an aluminate. For this reason, the aluminum slightly functions as electric charges. However, a part of aluminum serves as negative electric charges to form a target fixed polarization having a direction to cancel a fixed polarization. Negative electric charges of Al are collectively eccentrically distributed on the SiO₂ film 4. However, the amount of negative electric charge is insufficient. In contrast, a sufficient amount of negative electric charge of Ge can be eccentrically located on the interface.

Since Ta having a large ion radius is hard to be diffused in the high-dielectric-constant film, Ta is eccentrically located on the high-dielectric-constant film 8 in Variation 1. The fixed polarization by fixed electric charges in the pMISFET according to Variation 1 changes a flat band by about 650 mV. In this case, area densities of Ge on the SiO₂ film 4 and Ta on the HfSiON film 8 are 0.75×10¹⁴ cm⁻² and 1.5×10¹⁴ cm⁻², respectively, and the area densities are sufficient and well equal to those in Example 1. More specifically, an order of heat treatment and film formation process is not important for adding of Ge and Ta, since the localized sides of them are apparent.

However, when Al is added in place of Ge, Al can be distributed on both sides of the interface. For this reason, the order is important. Furthermore, when Si is substituted on the SiO₂ film 4 side, Al serves as a negative electric charge. For this reason, when Al is distributed near the channel, the mobility is deteriorated. In contrast, even though Si is substituted, Ge does not serve as a negative electric charge, and electrons need not be trapped in the film. For this reason, the mobility is not deteriorated.

Since an element having a large ion radius (in this case, Ta) is hard to be diffused in the high-dielectric-constant film, a doping position on an initial stage largely influences an amount of fixed polarity. A Ta₂O₅ film is formed on an HfSiON film, i.e., a structure including Si substrate 2/SiO₂ film 4/HfSiON film 8/Ta₂O₅ film. When Ta is diffused in the structure, Ta is taken into the HfSiON film in a structure of HfTa₂O₅ and tends to be stabilized. For this reason, there is a high possibility that a sufficient amount does not reach the interface between the SiO₂ film 4 and the HfSiON film 8. Thus, a sufficient fixed polarization is hard to be obtained even though a Ta₂O₅ or a Ta film is formed on the HfSiON film 8 and diffused.

When a laminated structure including a GeO₂ film and a Ta₂O₅ film is formed between the HfSiON film 8 and the gate electrode 10 and diffused, area densities of Ge in the SiO₂ film 4 and Ta in the HfSiON film 8 are about 0.5×10¹⁴ cm⁻². Since the amounts of Ge and Ta are insufficient, a fixed polarization of 200 mV is formed. Furthermore, Ge cannot help being distributed in HfSiON. Thus, the film is considerably deteriorated in the process and, especially, leakage increases. For example, a complex of Ge and an oxygen defect is formed, or Ge is vaporized from the film as GeO. Since Ta is taken into an entire area of the HfSiON film 8, Ta+ is uniformly distributed, thereby forming a film in which Ge is forced to be negative. This can be considered that Ta and Ge are taken into the HfSiON film 8 as a pair. More specifically, amounts of Ge and Ta sufficient for shifting cannot reach the interface of the SiO₂ film 4/HfSiON film.

SiGe is epitaxially grown on the Si substrate, and, similarly, a SiO₂ thermal oxide film and the HfSiO₂ film are formed on the SiGe layer obtained by forming an Si cap on the layer. At this time, as Ge reaches an interface between the SiO₂ film and the HfSiON film to shift a threshold value. However, a large number of interface levels between the Si substrate and the SiO₂ film are generated and thus a transistor function is hard to be realized.

More specifically, in order to dope Ge in the interface between the SiO₂ film and the HfSiON film, Ge is necessarily doped in the interface between the SiO₂ film and the HfSiON film from the initial stage.

### Comparative Example 1

In the manufacturing process of the laminated structure including the SiO₂ film 4 and the HfSiO film 8 in Example 1, a pMISFET in which both the GeO₂ film 6a and the Ta₂O₅ film 6b are not inserted is formed (not shown) as Comparative Example 1. At this time, it is considered that no fixed polarization is formed in the interface s, thereby an effective work function becoming as large as about 4.5 eV and that a threshold value is too large to function as the pMISFET.

(Variation 2)

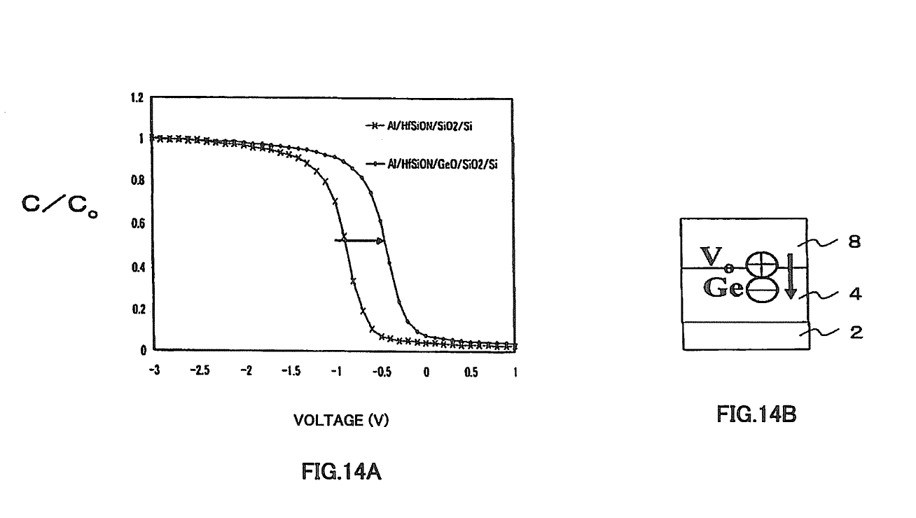

In the manufacturing process of the laminated structure including the SiO₂ film 4 and the HfSiO film 8 in Example 1, a pMISFET in which the Ta₂O₅ film 6b is not inserted and only the GeO₂ film 6a having a thickness of 0.3 nm is inserted is formed as Variation 2. As in Example 1, an HfSiON film is formed after an annealing process is performed at 600° C. for 10 seconds in an atmosphere of a gas mixture of Ar and nitrogen. Thereafter, an annealing process is performed at 1050° C. for 5 seconds in an atmosphere of a gas mixture of Ar and nitrogen. Ge is eccentrically located in the SiO₂ film 4, and a fixed polarization formed in the interface changes a flat band voltage by about 500 mV. In this case, an area density of Ge on the SiO₂ film 4 is 0.7×10¹⁴ cm⁻² and generates a fixed polarization of 500 mV. FIG. 14 shows a CV curve the threshold value of which moves. An ordinate in FIG. 14A shows C (capacitance)/Cₒ (in this case, Cₒ denotes a capacitance at a gate voltage of −3 V), and an abscissa in FIG. 14A shows V (gate voltage). The capacitance and the gate voltage are a those between the substrate and the gate electrode. As is apparent from FIG. 14A, when the GeO₂ film 6a is inserted between the SiO₂ film 4 and the HfSiO film 8, it is understood that the CV curve shifts to the right by about 500 my without being changed in shape in comparison with a case in which the GeO₂ film 6a is inserted. When Ge is more increased, a larger threshold value can be adjusted. Ta in Example 1 plays a role to attract Ge to the interface. However, in Variation 2, the role is played by an oxygen defect. An oxygen defect gives an electron to Ge and is stabilized by being paired with Ge. For this reason, as shown in FIG. 14B, Ge serves as a negative electric charge in the interface, and the oxygen defect serves as a positive electric charge. As a result, a fixed polarization having a sufficient size is generated.

(Variation 3)

As Variation 3 of Example 1, a pMISFET in which the Ta₂O₅ film 6b is not inserted and only the GeO₂ film 6a having a thickness of 0.3 nm is inserted is formed in the manufacturing process of the laminated structure including the SiO₂ film 4 and the HfSiO film 8 in Example 1. Before the laminated structure of SiO₂ film 4/GeO₂ film 6a/HfSiON film 8 is formed, fluorine ions are implanted in the channel. At this time, an implantation area density of F is set to 1×10¹⁵ cm⁻², and an implantation energy is set to 10 keV. In the following description, unless otherwise noted, F ions are implanted in the condition described above.

In Variation 3, the SiO₂ film serving as a sacrificial film having 1 nm is formed on the SiO₂ film, and fluorine ions are implanted in the SiO₂ film through the SiO₂ film. Then, the sacrificial film is peeled once. Thereafter, the SiO₂ film, the GeO₂ film 6a, and the HfSiON film 8 are sequentially formed. In the forming step, an annealing process is performed at 600° C. for 10 seconds in an atmosphere of a gas mixture of Ar and nitrogen after the GeO₂ film 6a is formed, as in Example 1. Then, an annealing process is performed at 1050° C. for 5 seconds in an atmosphere of a gas mixture of Ar and nitrogen after the HfSiON film 8 is formed.

In the pMISFET according to Variation 3, a fixed polarization generated in the interface is enough to change a flat band voltage by about 700 mV. In Variation 3, most of fluorine ions in the channel can be concentrated on the interface between the SiO₂ film 4 and the HfSiO film 8 by the annealing process performed at 1050° C. for 5 seconds in the atmosphere of the gas mixture of Ar and nitrogen.

In Variation 3, the fluorine is not diffused in the insulating film, and most of the fluorine remains in the channel, since the annealing process used to diffuse Ge in the SiO₂ film 4 is performed at a low temperature of 600° C. Thereafter, almost all fluorine is diffused from the channel outward into the gate insulating films 4 and 8, in the high-temperature heat treatment (1050° C.) performed after the HfSiON film 8 is formed. The fluorine substitutes for oxygen and is fixed since the fluorine is very stable in the interface between the SiO₂ film 4 and the HfSiO film 8 in which Ge is diffused. At this time, the fluorine effectively serves as a positive fixed electric charge, since the subjected fluorine has the number of negative electric charges which is smaller than that of oxygen by 1. In this manner, even though oxygen defects are short, a positive electric charge can be secured. Since the negative electric charges obtained by Ge are concentrated in the SiO₂ film 4, a large fixed polarization is generated. Conventionally, a channel is formed to have a profile similar to that of a buried channel by using only low-temperature heat treatment, when a threshold voltage is controlled by using diffusion of fluorine. In this case, a shift of a very high flat band voltage cannot be desired due to deterioration of the channel when an excessive amount of fluorine is doped. Conventionally, the shift amount is about 200 mV at most.

In Variation 3, Ge is segregated in the SiO₂ film 4, and fluorine is segregated in the interface, so that a shift of 700 mV is realized. The area density of Ge in the SiO₂ film 4 is sufficient of about 1.2×10¹⁴ cm⁻². A peak position has a distance of 0.65 Å from the interface, and the peak is considerably sharp. An amount of the fluorine in the interface is twice the amount of Ge, i.e., about 2.4×10¹⁴ cm⁻². It is a characteristic of the configuration in which the fixed polarization by Ge and F is present in the interface of the SiO₂ film 4 and the HfSiON film 8, that the amount of fluorine is twice the amount of Ge. Here, when a distribution of the fluorine in a film thickness direction is measured by SIMS, a sharp peak is formed in the interface between the SiO₂ film 4 and the HfSiON film 8, which is an interface position. At a position other than the interface, the fluorine is diffused outward and discharged to the outside. Three-dimensional distributions of the positions of Ge and F are measured by using the atom probe described above. According to the measurement results, a peak of Ge is located on the SiO₂ film 4 side with reference to the interface, and a peak of F is located at an interface position. More specifically, the peak position of Ge is closer to the Si substrate than the peak position of F, and is present in the SiO₂ film. A peak interval is 0.64 Å, and thus Ge is distributed in the SiO₂ film 4 within a thickness of just one layer from the interface position which is the peak position of F.

In the process of doping F in the interface, especially, in the interface between the SiO₂ film and the high-dielectric-constant film, oxygen defects are buried with F. As a result, a long-time voltage application characteristic (BTI:Bias Temperature Instability) is considerably improved. Especially, annealing in oxygen is not required since the oxygen defects are buried with F. When F was not doped, a small shift of the threshold value such as about 10 mV occurred for 10 hours without oxygen annealing. However, when F was doped, shift was rarely observed for 3 days without oxygen annealing.

### Example 2

A CMISFET according to Example 2 of the present invention will be described.

Although not described in detail, an MISFET is formed using a threshold adjusting method by adding La which is conventionally used, and a pMISFET is formed having a structure described in Example 1 of the present invention, and thus a CMIS device having a low threshold voltage can be manufactured. In this manner, a CMIS device can be very easily formed by partially employing the conventional configuration and partially employing the configuration of Example 1 of the present invention.

Alternatively, As may be distributed on an SiO₂ film side to form a fixed polarization between As and N in the interface in the nMISFET. The process will be briefly described below.

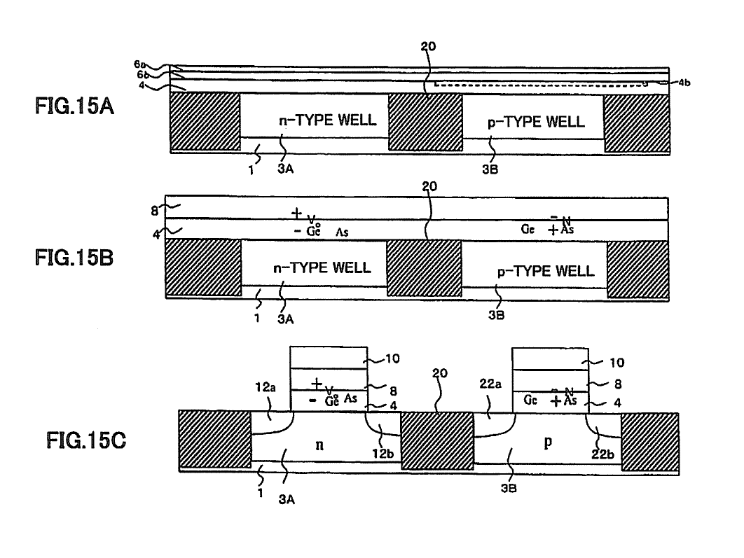

FIGS. 15A, 15B, and 15C are schematic diagrams for explaining a method of manufacturing a CMISFET according to a second embodiment. As shown in FIG. 15A, a silicon substrate 1 is prepared, and a first element region to form a pMISFET and a second element region to form an nMISFET are provided on the silicon substrate 1. The first and second element regions are semiconductor regions which are insulated from each other by an element isolation region 20. The semiconductor region may be a part of the semiconductor substrate (the silicon substrate 1 in the example) or may be an n-type well region 3A and a p-type well region 3B formed on the semiconductor substrate.

As in the first embodiment, the SiO₂ film 4 is formed on the entire surface of the silicon substrate 1. The forming region 3A of the pMISFET is covered with a resist (not shown). A surface 4b of the SiO₂ film 4 in the forming region 3B for the nMISFET is nitrided by room-temperature plasma nitriding. The resist is removed, and an As₂O₅ film 6c having a film thickness of 0.2 nm and the GeO₂ film 6a having a film thickness of 0.3 nm are laminated to form a pMISFET and an nMISFET. As shown in FIG. 15B, a HfSiON film 8 is formed after an annealing process is performed at 600° C. for 10 seconds in an atmosphere of a gas mixture of Ar and nitrogen. Then, an annealing process is performed at 1050° C. for 5 seconds in an atmosphere of a gas mixture of Ar and nitrogen. Thereafter, the gate electrode 10 is formed, with which the HfSiON film 8 and the SiO₂ film 4 are patterned, and impurities are doped in the n-type well 3A and the p-type well 3B, respectively, to form source regions 12a and 22a and drain regions 12b and 22b. Thus, a CMISFET is formed as shown in FIG. 15C.

As shown in FIG. 15B, in the pMISFET, Ge is eccentrically located on the SiO₂ film 4 side, a fixed polarization (fixed polarization configured by Ge having a negative electric charge and eccentrically located in SiO₂ and an oxygen defect having a positive electric charge and located in an interface) generated in the interface changes a flat band voltage by 700 mV. An area density of Ge on the SiO₂ film side is about 1.2×10¹⁴ cm⁻² which is sufficient as an amount of electric charge generated by only Ge and generates a fixed polarization of 700 mV. In this manner, a pMISFET having a low threshold value can be formed.

As shown in FIG. 15B, in the nMISFET, As is eccentrically located on the SiO₂ film 4 side, a fixed polarization (fixed polarization configured by N having a negative electric charge and located in the interface and As having a positive electric charge and eccentrically located in SiO₂) generated in the interface changes a flat band voltage by 200 mV. An area density of As on the SiO₂ film side is about 0.7×10¹⁴ cm⁻² which is sufficient as an amount of electric charge generated by only As. At this time, As and N in the interface generate a fixed polarization oriented to an nMIS. In this manner, an nMISFET having a low threshold value can be formed.

At this time, effective work functions at band edges can be obtained in both the pMISFET and the nMISFET, and a low-threshold CMISFET can be realized.

In the example, it is important that As and Ge are doped in the entire area without discriminating the nMISFET forming region and the pMISFET forming region. The nMISFET and the pMISFET can be distinctively formed by merely employing the nitriding process of the nMISFET forming region only.

According to the second embodiment, the conventional methods are used in the process of forming the SiO₂ film and the HfSiON film and any special method for forming the film is not used. The same conventional annealing method for a laminated film including an SiO₂ film and an HfSiON film may be used for annealing As

Important points are that Ge inserted between the SiO₂ film and the high-dielectric-constant film is eccentrically located in the SiO₂ film and that Ge receives an electron in the interface to serve as a negative electric charge.

Of other ions, ions each having a large radius may be diffused into the HfSiON film, and ions each having a small radius may be diffused in the SiO₂ film. An electric charge is determined by a valence difference with a tetravalent base material.

When an appropriate combination described in the specification is considered, a pMISFET and an nMISFET each having a sufficiently small threshold voltage can be realized. Therefore, a CMIS device having a sufficiently small threshold voltage can be realized.

The embodiment describes the configuration in which the nMISFET and the pMISFET can be easily distinctively formed depending on the presence/absence of nitriding.

According to Example 1, Example 2, or a modification thereof, a MISFET having an effective work function at a band edge of silicon can be obtained.

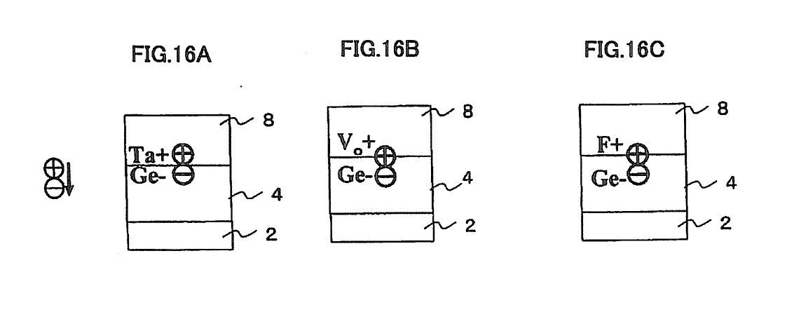

As shown in FIG. 16, additives to design a low-threshold structure of the pMISFET will be briefly described. As shown in FIG. 16A, a material (Ge) serving as a negative electric charge on the SiO₂ film 4 side and a material (V, Nb, Ta, Mo, W, Sb, Bi, Te, or Po) serving as a positive electric charge on the high-dielectric-constant film side such as the HfSiON film 8 are used. As shown in FIGS. 16B and 16C, an oxygen defect Vo in the interface or F (fluorine) serves as a positive electric charge. As shown in FIGS. 16A to 16C, when the above positive and negative electric charges are well combined to each other, positive electric charges on the substrate 2 side and negative electric charges on the electrode 10 side may be arranged in the order named to form a fixed polarization.

In addition, N (nitrogen) in the interface serving as a negative electric charge is useful to form the configuration of the CMOS.

In the above description, the MISFETs according to the embodiment are formed on a silicon substrate. However, the substrate is not limited to a silicon substrate. A silicon layer may be formed on a substrate other than the silicon substrate, for example, a glass substrate to form a MISFET according to each of the embodiments. Alternatively, a concept of an embodiment of the present invention can be directly applied to all semiconductor substrate of compound semiconductor substrates such as a Ge substrate, an SiC substrate, a GaAs substrate, and a GaN substrate. In this case, since a band edge position changes, an optimum effective work function may be changed according to the band edge position. In a compound semiconductor substrate such as a Ge substrate, if the same processes as those in the Si substrate are performed, a MISFET can be formed. A difference between the compound semiconductor substrate and the Si substrate is only that optimum work functions are different. For example, in the Ge substrate, 4.0 eV is an optimum value oriented to an nMISFET, and 4.66 eV is an optimum value oriented to a pMISFET. To each of the substrates, an appropriate number of dipoles may be formed by the method described in an embodiment of the present invention.

In each of the embodiments, a source region and a drain region are formed by impurity regions in which a p-type or n-type impurity is doped in a MISFET. A MISFET in which a source region and a drain region are formed by a meal layer which is in direct contact with a p-type semiconductor substrate or an n-type semiconductor substrate, i.e., a Schottky MISFET may be used.

In each of the embodiments described above, a so-called gate-first scheme is described. However, a so-called gate-last scheme in which a gate insulating film and a gate electrode are formed after an impurity diffusion layer is formed may be used.

As described above, according to each of the embodiments of the present invention, a MIS transistor which can operate with a low threshold value can be obtained.

The present invention is not limited to the above embodiments only and can be embodied by modifying components thereof without deviating from the scope thereof when the present invention is carried out. Various inventions can be formed by appropriately combining a plurality of components disclosed in the above embodiments. For example, some components may be deleted from all components shown in an embodiment. Further, components common to different embodiments may appropriately be combined.

What is claimed is:

1. A field effect transistor comprising:
an n-type semiconductor region; a source region and a drain region, each separately formed in the n-type semiconductor region;
a first insulating film formed on the n-type semiconductor region between the source region and the drain region and containing silicon and oxygen;
a second insulating film formed on the first insulating film and containing at least one element selected from the group consisting of Hf, Zr, and Ti and oxygen;
and a gate electrode formed on the second insulating film,
wherein Ge is doped in an interface region including an interface between the first insulating film and the second insulating film, and an area density of the Ge has a peak on a first insulating film side in the interface region.

2. The field effect transistor according to claim 1, wherein fluorine is doped in the interface region, an area density of the fluorine has a peak in the interface region, and the peak of the area density of the Ge is closer to the first insulating side than the area density of the fluorine.

3. The field effect transistor according to claim 2, wherein the peak of the area density of the Ge is located at a position having a distance of less than 1.4 Å from the interface.

4. The field effect transistor according to claim 3, wherein the area density falls within the range of
0.7×10¹⁴ cm⁻²≦[Ge]cm⁻²≦2.1×10¹⁴ cm⁻²
when the area density at the peak of the Ge is given by [Ge]cm⁻².

5. The field effect transistor according to claim 2, wherein the area density satisfies

|[Ge]×2−[F]|cm⁻²≦1.7×10¹³ cm²
when an area density at the peak of the fluorine is given by [F]cm⁻².

6. The field effect transistor according to claim 1, wherein the peak of the area density of the Ge is located at a position having a distance of less than 1.4 Å from the interface.

7. The field effect transistor according to claim 6, wherein the area density falls within the range of
7×10¹⁴ cm⁻²≦[Ge]cm⁻²≦2.1×10¹⁴ cm⁻²
when an area density at the peak of the Ge is given by [Ge]cm⁻².

8. The field effect transistor according to claim 1, wherein at least one additive element selected from V, Nb, Ta, Mo, W, Sb, Bi, Te, and Po is doped in the interface region, and an area density of the additive element has a peak on the second insulating film side in the interface region.

9. The field effect transistor according to claim 8, wherein the peak of the area density of the Ge is located at a position having a distance of less than 1.4 Å from the interface, and the peak of the area density of the additive element is located at a position having a distance of not more than 3.2 Å from the interface.

10. The field effect transistor according to claim 9, wherein 1.0×10¹⁴ cm⁻²≦[Ge]cm⁻²×2≦3.0×10¹⁴ cm⁻², 1.0×10¹⁴ cm⁻²≦[A2]cm⁻²×k≦3.0×10¹⁴ cm⁻², and [Ge]×2−[A2]×k|cm⁻²≦1.2×10¹³ cm⁻² are satisfied, provided that the area density at the peak of the Ge is given by [Ge]cm⁻², that the area density at the peak of the additive element is given by [A2]cm⁻², that k=2 is satisfied when the additive element is Mo, W, Te, or Po, and that k=1 is satisfied when the additive element is V, Nb, Ta, Sb, or Bi.

11. A method for manufacturing a field effect transistor, comprising the steps of:
forming a first insulating film on an n-type semiconductor region;
depositing a material containing Ge on the first insulating film;
forming a second insulating film to cover the material containing the Ge;
heating for diffusing the material containing the Ge in an interface region including an interface between the first insulating film and the second insulating film;
forming a gate electrode on the second insulating film; and
forming a source region and a drain region which are separated from each other in the n-type semiconducotr region by using the gate electrode as a mask.

12. The method for manufacturing a field effect transistor according to claim 11, wherein the material containing the Ge is germanium, a germanium oxide, or a metal germanide.

13. The method for manufacturing a field effect transistor according to claim 11, further comprising the step of;
depositing a material containing at least one additive element selected from V, Nb, Ta, Mo, W, Sb, Bi, Te and Po between the step of depositing the material containing the Ge and the step of forming the second insulating film on the deposited material.

14. The method for manufacturing a field effect transistor according to claim 11, further comprising the step of;
heating the material containing the Ge at a temperature lower than that in the heat treatment step of diffusing the material containing the Ge in the first insulating film, between the step of depositing the material containing Ge on the first insulating film and the step of forming the second insulating film.

15. The method for manufacturing a field effect transistor according to claim 11, further comprising the step of implanting fluorine (F) ions in a surface region of the n-type semiconductor region, between the step of depositing the material containing the Ge and forming the second insulating film on the surface region.

16. A method for manufacturing a complementary field effect transistor, comprising the steps of:
forming a first element region and a second element region on a semiconductor substrate;
forming a first insulating film on an entire area on the semiconductor substrate;
nitriding a surface of the first insulating film on the second element region in the first and second element regions;
depositing a material containing phosphorous (P), arsenic (As), sulfur (S), and selenium (Se) and a material containing Ge;
forming a second insulating film to cover the material containing the Ge;
first heat treatment for diffusing the material containing the Ge in an interface region including an interface between the first insulating film and the second insulating film;
forming a gate electrode on the second insulating film;
forming a source region and a drain region which are separated from each other in the first element region and the second element region by using the gate electrode as a mask.

17. The method for manufacturing a complementary field effect transistor according to claim 16, wherein the semiconductor substrate is a silicon semiconductor substrate, the first element region and the second element region are n-type well and a p-type well which are separated by an element isolation region, and the first insulating film is a silicon oxide.

18. The method for manufacturing a complementary field effect transistor according to claim 16, wherein the material containing the Ge is germanium, a germanium oxide, or a metal germanide.

19. The method for manufacturing a complementary field effect transistor according to claim 16, wherein the material containing phosphorous (P), arsenic (As) sulfur (S) and selenium (Se) are phosphorous oxide, arsenic oxide, sulfur oxide and selenium oxide, respectively.
